(19) United States
(12) Patent Application Publication
(10) Pub. No.: US 2026/0075890 A1
(43) Pub. Date: Mar. 12, 2026

(54) SEMICONDUCTOR DEVICES WITH CUT GATE INSULATION FEATURES

(71) Applicant: Taiwan Semiconductor Manufacturing Company, Ltd., Hsinchu (TW)

(72) Inventors: Tsung-Chieh Hsiao, Changhua County (TW); Wei-Yuan Lee, Hsinchu City (TW); Chih-Lin Wang, Zhubei City (TW)

(73) Assignee: Taiwan Semiconductor Manufacturing Company, Ltd., Hsinchu (TW)

(21) Appl. No.: 18/883,521

(22) Filed: Sep. 12, 2024

(51) Int. Cl. H10D 62/10; H10D 30/01; H10D 30/62

(52) U.S. Cl. CPC H10D 62/115; H10D 30/024; H10D 30/6211

(57) ABSTRACT

Semiconductor devices and methods for fabricating semiconductor devices are described. A method includes forming active regions over a semiconductor substrate; forming a shallow trench isolation (STI) feature over the semiconductor substrate and between the active regions, wherein the STI feature contacts an upper surface of the semiconductor substrate; forming a gate structure over the active regions and over the STI feature; cutting the gate structure by etching through the gate structure and into the STI feature to form a trench, wherein the trench is distanced from the upper surface of the semiconductor substrate; and forming an insulation feature in the trench.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIGS. 18A and 18B illustrate the cross-sectional views and perspective views of intermediate stages in the formation of semiconductor devices in accordance with some embodiments.

FIG. 19 is a flow chart illustrating a method in accordance with some embodiments.

FIGS. 20-24 and 26-28 are cross-sectional views of a device during successive stages of fabrication and taken along line Y-Y in FIG. 31.

FIGS. 25 and 29 are cross-sectional views taken along line X-X in FIG. 31 of the same fabrication stage as the respective preceding Figure.

FIG. 30 is a focused view of a portion of FIG. 28.

FIG. 31 is an overhead layout view of a device in accordance with some embodiments.

FIGS. 32-34 and 36-38 are cross-sectional views of a device during successive stages of fabrication and taken along line Y-Y in FIG. 31.

FIGS. 35 and 39 are cross-sectional views taken along line X-X in FIG. 31 of the same fabrication stage as the respective preceding Figure.

FIG. 40 is a focused view of a portion of FIG. 38.

FIG. 41 is a flow chart illustrating a method in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 99 wt. % of tungsten.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many typical processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Transistor devices and the methods of forming the same are provided in accordance with various exemplary embodiments. The intermediate stages of forming the transistors are illustrated in accordance with some embodiments. Some variations of some embodiments are discussed. Throughout the various views and illustrative embodiments, like reference numbers are used to designate like elements. In the illustrated exemplary embodiments, the formation of Fin Field-Effect Transistors (FinFETs) is used as an example to explain the concept of the present disclosure. Planar transistor devices, gate-all-around (GAA) devices or other devices may also be formed adopting the embodiments of the present disclosure.

Presented herein are embodiments of semiconductor devices and of methods for fabricating such devices. Methods described herein may be easily integrated into the current process flow. Further, methods described herein relate to the formation of cut-gate-insulation features.

In embodiments herein, metal gates or gate structures are cut into discrete gate segments. Then a cut-gate-insulation feature is formed between the gate segments, such as to insulate the gate segments from one another.

When the underlying semiconductor substrate is etched during the process for cutting the metal gates or gate structures into discrete gate segments, a substrate leakage path may be created, particularly from NMOS to PMOS regions, such as from an NMOS device to an N-well in the PMOS region. For example substrate leakage from NMOS to PMOS may be established when depositing silicon nitride in the etched portion of the substrate to form the cut-gate-insulation features. Nevertheless, the semiconductor substrate is often cut to ensure successful removal of metal gate material to define discrete gate segments.

In certain embodiments herein, cut-gate-insulation features are formed over the underlying semiconductor substrate without extending into the semiconductor substrate. Thus, such embodiments enhance minimum leakage current at OFF-state and elevate the trigger voltage performance by blocking a substrate leakage path from NMOS to N-well.

Certain embodiments provide a method for forming cut-gate-insulation features in which the etch process for cutting the metal gates or gate structures does not etch or cut the underlying semiconductor substrate. As a result, substrate leakage, such as from NMOS to PMOS regions is avoided.

In certain embodiments, the metal gate cut process etch is closely monitored so that a remaining portion of STI feature remains under the trench formed by the metal gate cut process etch. Thus, the underlying semiconductor substrate is not etched. In such embodiments, the etch depth may be controlled such that the resulting trench extends into the STI for a depth of from 50 to 95% of the thickness of the STI feature. In other words, the remaining portion of the STI feature under the trench has a thickness of from 5 to 50% of the total STI feature thickness.

Other embodiments avoid etching the semiconductor substrate during the metal gate cut process by first locating an etch stop layer on the semiconductor substrate where the gate cut will occur. Thus, the metal gate cut process etch may land on the etch stop layer. Such embodiments may provide for improved depth consistency, while using an additional masking process to outline the etch stop layer before etching the STI feature during the metal gate cut process.

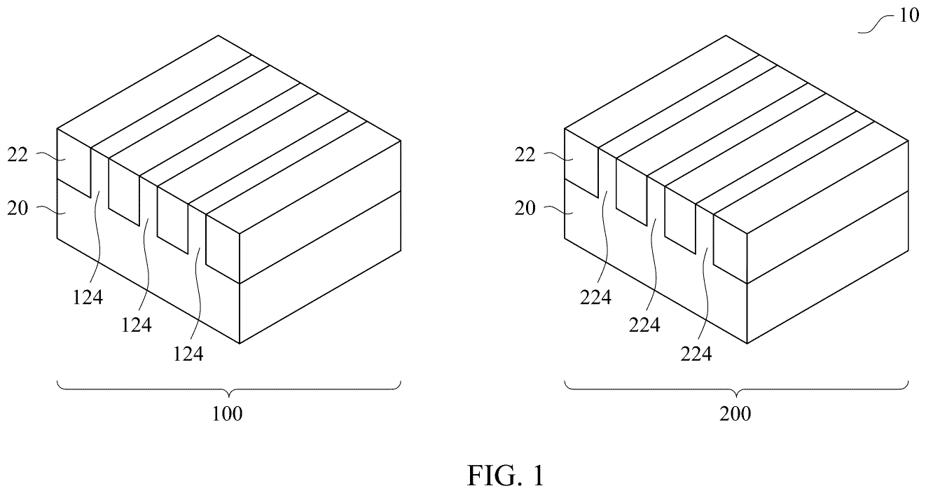

FIG. 1 illustrates a perspective view of an initial structure 10. The initial structure 10 includes substrate 20. Substrate 20 may be a semiconductor substrate, which may be a silicon substrate, a silicon germanium substrate, or a substrate formed of other semiconductor materials. In accordance with some embodiments of the present disclosure, substrate 20 includes a bulk silicon substrate and an epitaxy silicon germanium (SiGe) layer or a germanium layer (without silicon therein) over the bulk silicon substrate. Substrate 20 may be doped with a p-type or an n-type impurity. Isolation regions 22 such as Shallow Trench Isolation (STI) regions may be formed to extend into substrate 20. The portions of substrate 20 between neighboring STI regions 22 are referred to as semiconductor strips 124 and 224, which are in device regions 100 and 200, respectively. Device region 100 is a p-type transistor region, in which a p-type transistor such as a p-type FinFET is to be formed. Device region 200 is an n-type transistor region, in which an n-type transistor such as an n-type FinFET is to be formed.

STI regions 22 may include a liner oxide (not shown). The liner oxide may be formed of a thermal oxide formed through a thermal oxidation of a surface layer of substrate 20. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). STI regions 22 may also include a dielectric material over the liner oxide, and the dielectric material may be formed using Flowable Chemical Vapor Deposition (FCVD), spin-on coating, or the like.

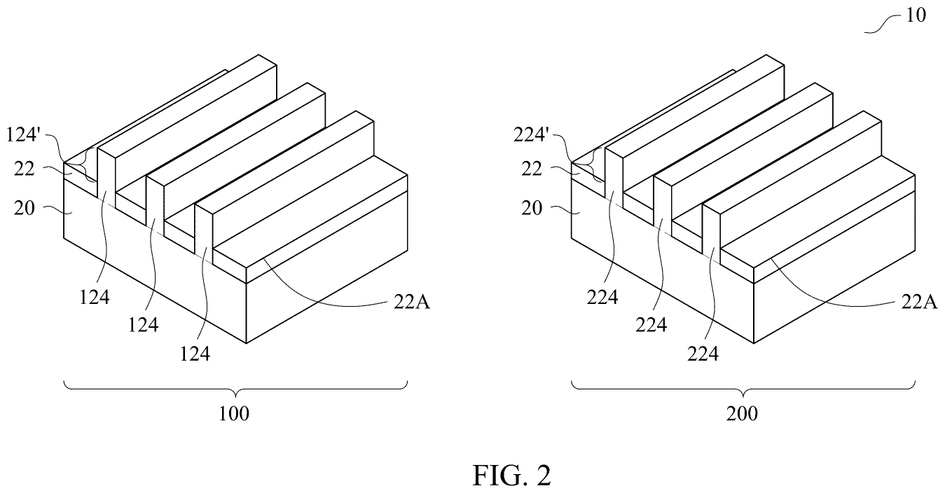

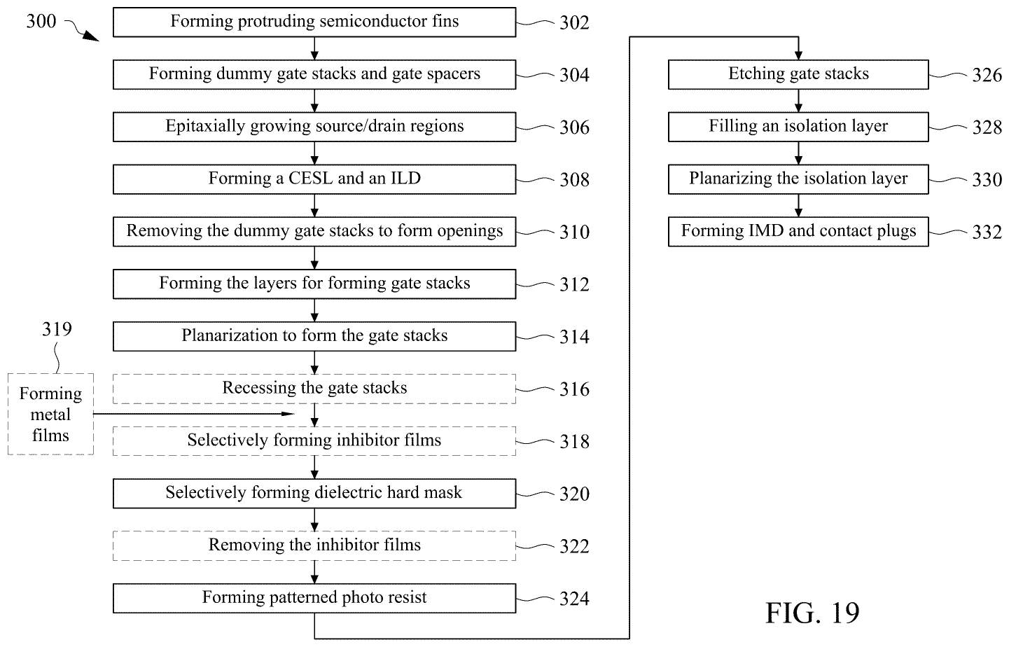

Referring to FIG. 2, STI regions 22 are recessed, so that the top portions of semiconductor strips 124 and 224 protrude higher than the top surfaces 22A of the neighboring STI regions 22 to form protruding fins 124′ and 224′, or active regions 124′ and 224′. The respective step is illustrated as step S302 in the process flow shown in FIG. 19. The etching may be performed using a dry etching process, wherein NH3 and NF3 are used as the etching gases. During the etching process, plasma may be generated. Argon may also be included. In accordance with alternative embodiments of the present disclosure, the recessing of STI regions 22 is performed using a wet etch process. The etching chemical may include diluted HF, for example.

In above-illustrated exemplary embodiments, the defining of the patterns of the fins may be achieved by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

The materials of protruding fins 124′ and 224′ may also be replaced with materials different from that of substrate 20. For example, protruding fins 124′ may be formed of Si, SiP, SiC, SiPC, or a III-V compound semiconductor such as InP, GaAs, AlAs, InAs, InAlAs, InGaAs, or the like. Protruding fins 224′ may be formed of Si, SiGe, SiGeB, Ge, or a III-V compound semiconductor such as InSb, GaSb, InGaSb, or the like.

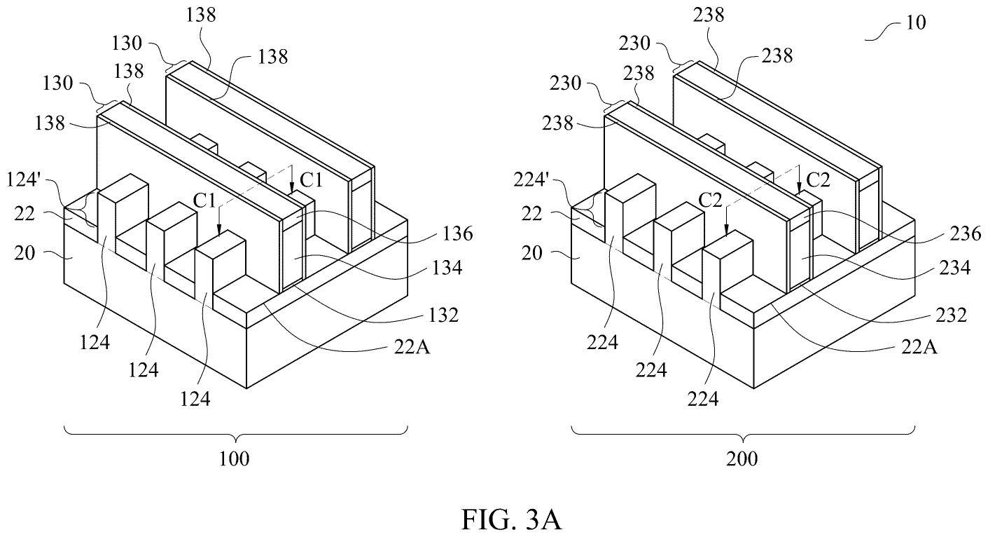

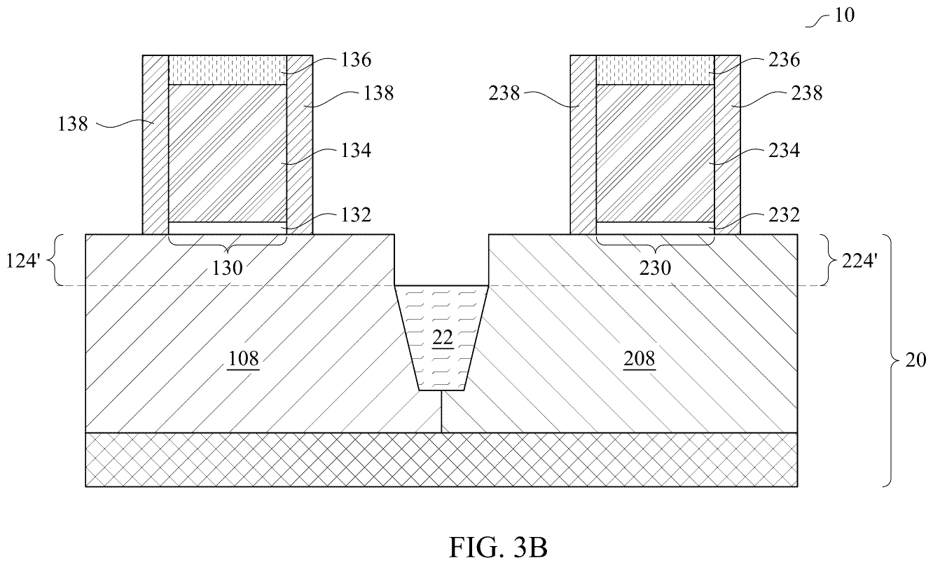

Referring to FIG. 3A, dummy gate stacks 130 and 230 are formed on the top surfaces and the sidewalls of protruding fins 124′ and 224′, respectively. The respective step is illustrated as step S304 in the process flow shown in FIG. 19. Dummy gate stacks 130 may include gate dielectrics 132 and dummy gate electrodes 134 over dummy gate dielectrics 132. Dummy gate stacks 230 may include gate dielectrics 232 and dummy gate electrodes 234 over dummy gate dielectrics 232. Dummy gate electrodes 134 and 234 may be formed, for example, using polysilicon, and other materials may also be used. Each of dummy gate stacks 130 and 230 may also include hard mask layers 136 and 236. Hard mask layers 136 and 236 may be formed of SiN, SiO, SiC, SiOC, SiON, SiCN, SiOCN, TiN, AlON, Al2O3, or the like. The thickness of hard mask layers 136 and 236 may be in the range between about 10 nm and about 60 nm. Each of dummy gate stacks 130 and 230 crosses over a single one or a plurality of protruding fins 124′ and 224′, respectively. Dummy gate stacks 130 and 230 may also have lengthwise directions perpendicular to the lengthwise directions of the respective protruding fins 124′ and 224′, respectively.

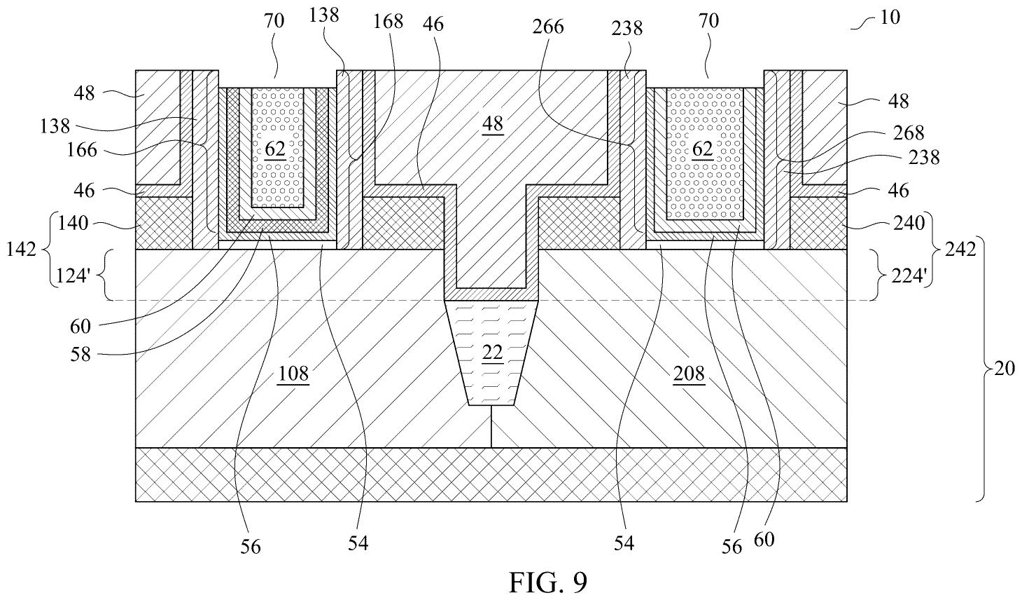

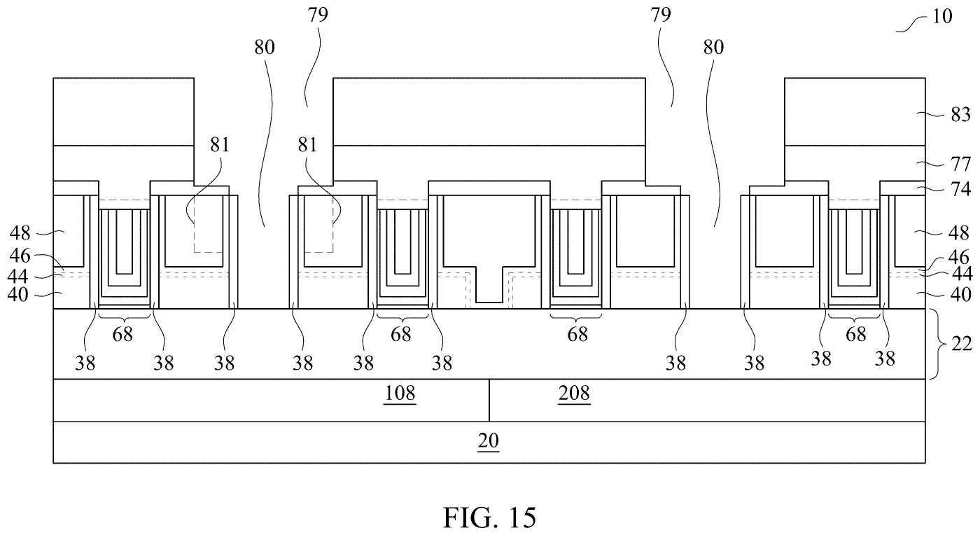

FIG. 3B illustrates a cross-sectional view of device regions 100 and 200 in accordance with some embodiments. The cross-sectional view combines the cross-sectional view obtained from the vertical plane containing line C1-C1 in FIG. 3A and the cross-sectional view obtained from the vertical plane containing line C2-C2 in FIG. 3A, with an STI region 22 separating device regions 100 and 200 in FIG. 3B. Protruding fins 124′ and 224′ are illustrated schematically. Also, n-well region 108 and p-well region 208 are formed to extend into protruding fins 124′ and 224′, respectively. N-well region 108 and p-well region 208 may also extend into the bulk portion of semiconductor substrate 20 lower than STI regions 22. Unless specified otherwise, the cross-sectional views in subsequent figures (except FIGS. 9B and 15) may also be obtained from planes same as the vertical planes as shown in FIG. 3A, which planes contain lines C1-C1 and C2-C2, respectively.

Next, as also shown in FIGS. 3A and 3B, gate spacers 138 and 238 are formed on the sidewalls of dummy gate stacks 130 and 230, respectively. In the meantime, fin spacers (not shown) may also be formed on the sidewalls of protruding fins 124′ and 224′. In accordance with some embodiments of the present disclosure, gate spacers 138 and 238 are formed of an oxygen-containing dielectric material(s) such as silicon oxynitride (SiON), silicon oxy-carbo-nitride (SiOCN), silicon oxide (SiO2), silicon oxycarbide (SiOC), or the like. Non-oxygen-containing materials such as silicon nitride (SiN) and/or silicon carbide (SiC) may also be used, depending on the formation method of the subsequently formed inhibitor film. Gate spacers 138 and 238 may include air-gaps, or may formed as including pores, and may have a single-layer structure or a multi-layer structure including a plurality of dielectric layers.

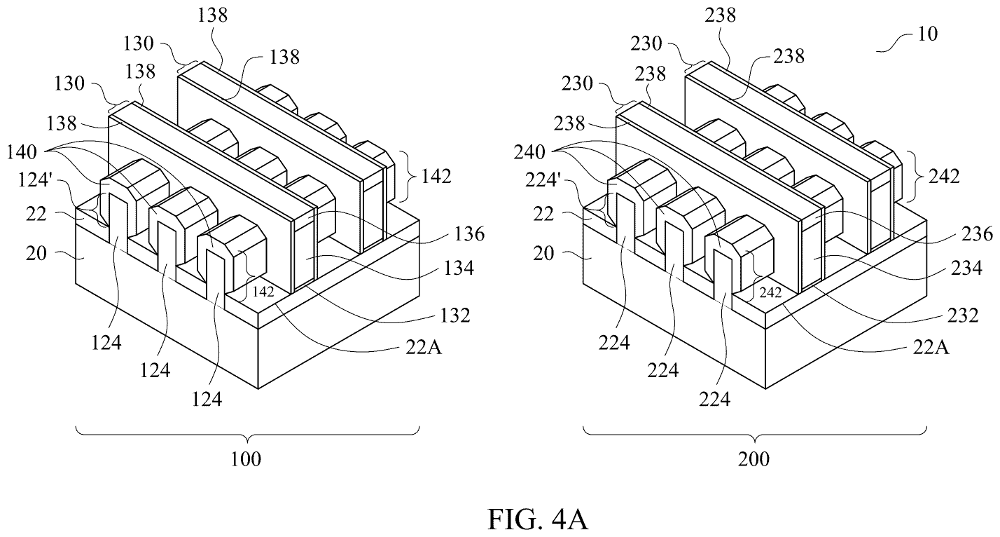

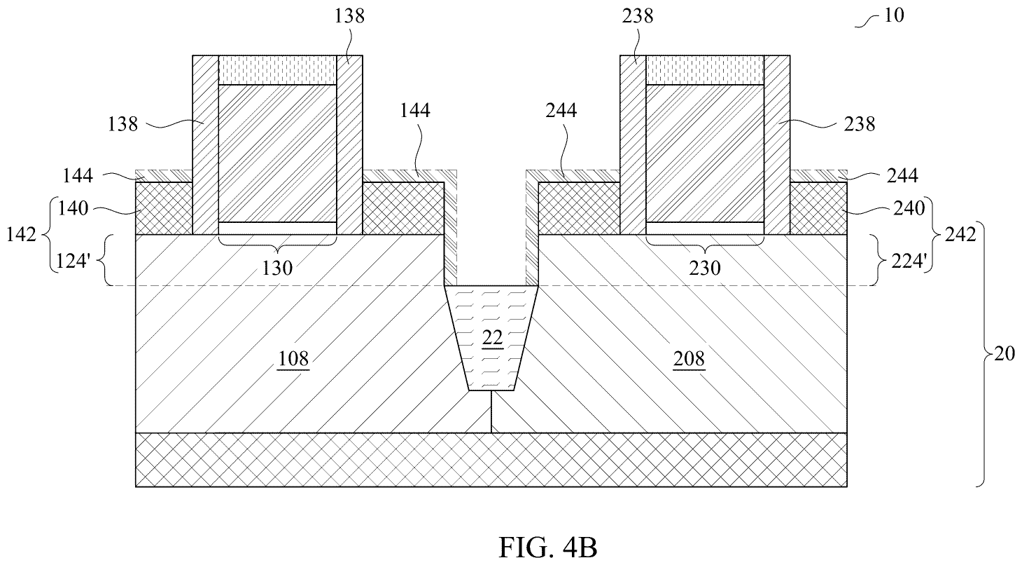

FIGS. 4A and 4B illustrate the formation of source/drain regions 142 and 242 in device regions 100 and 200, respectively. In accordance with some embodiments of the present disclosure, epitaxy regions 140 and 240 are grown on protruding fins 124′ and 224′, respectively, forming cladding source/drain regions. The respective step is illustrated as step S306 in the process flow shown in FIG. 19. Epitaxy regions 140 and 240 may be doped with a p-type impurity and an n-type impurity, respectively, which may be in-situ doped with the during the epitaxy. In accordance with some embodiments of the present disclosure, epitaxy regions 140 includes Si, SiGe, SiGeB, Ge or a III-V compound semiconductor such as InSb, GaSb, InGaSb, or the like. Epitaxy regions 240 may include Si, SiP, SiC, SiPC, or a III-V compound semiconductor such as InP, GaAs, AlAs, InAs, InAIAs, InGaAs, or the like. The thickness of epitaxy regions 140 and 240 may be in the range between about 3 nm and about 30 nm.

After the epitaxy step, epitaxy regions 140 and protruding fin 124′ may be further implanted with a p-type impurity to form source and drain regions 142. Epitaxy regions 240 and protruding fins 224′ may be further implanted with an n-type impurity to form source and drain regions 242. In accordance with alternative embodiments of the present disclosure, the implantation steps are skipped, for example, when epitaxy regions 140 and 240 have been in-situ doped with the p-type and n-type impurities, respectively.

In accordance with some embodiments of the present disclosure, instead of forming cladding source/drain regions, an etching step (referred to as source/drain recessing hereinafter) is performed to etch the portions of protruding fins 124′ and 224′ that are not covered by dummy gate stack 130/230 and gate spacers 138/238. The etching may be anisotropic, and hence the portions of fins 124′ and 224′ directly underlying dummy gate stacks 130 and 230 and gate spacers 138 and 238 are protected, and are not etched. Recesses (not shown) are accordingly formed between STI regions 22. Epitaxy source/drain regions are then grown from the recesses.

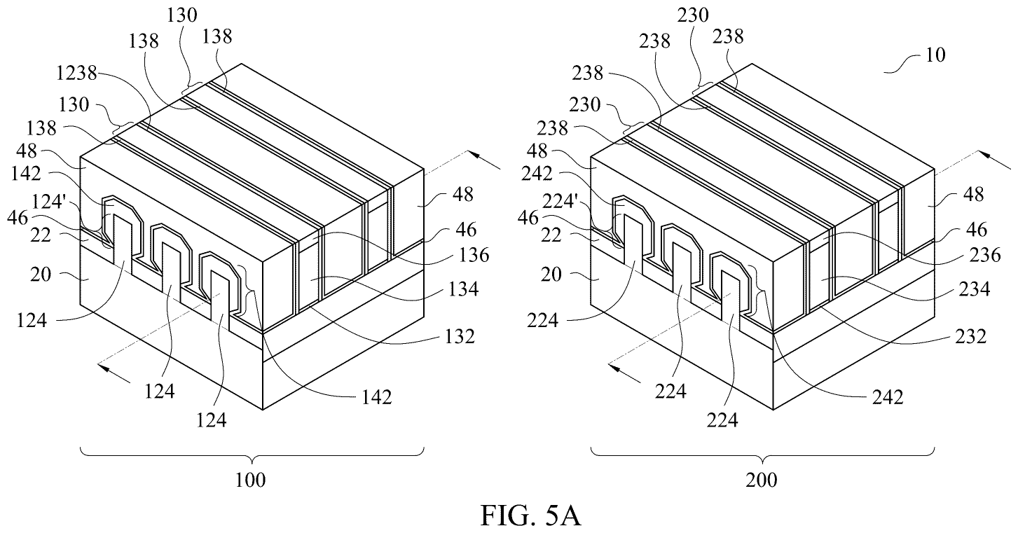

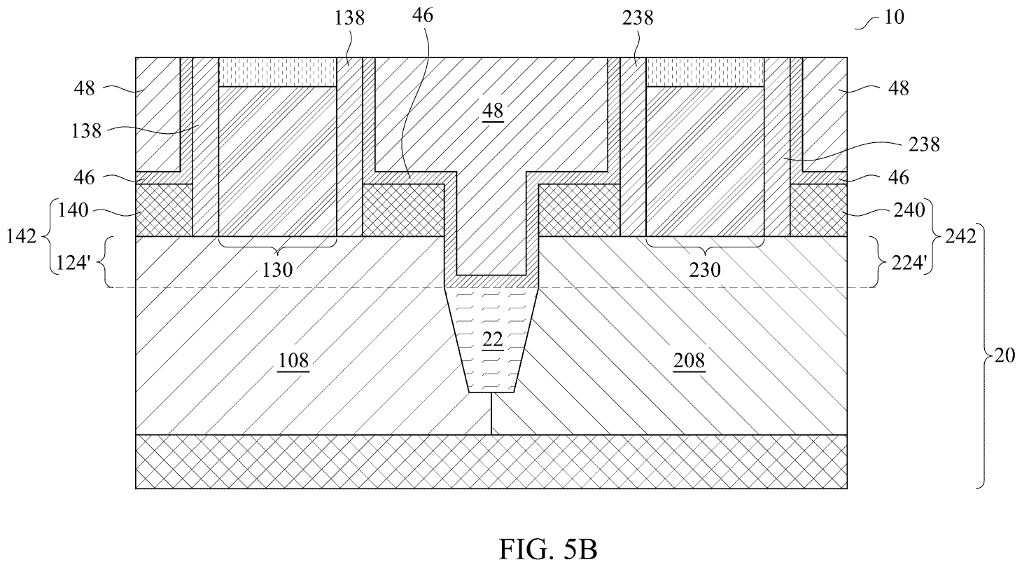

FIG. 4B also schematically illustrates source/drain silicide regions 144 and 244 respectively, which may be formed by depositing a blanket metal layer, performing an anneal to react the blanket metal layer with source/drain regions 142 and 242, and removing the un-reacted portions of the metal layer. The metal for forming source/drain silicide regions 144 and 244 may include Ti, Co, Ni, NiCo, Pt, NiPt, Ir, PtIr, Er, Yb, Pd, Rh, Nb, or the like. In accordance with alternative embodiments, source/drain silicide regions are formed after the formation of replacement metal gates, and are formed through contact openings, which penetrate through Inter-Layer Dielectric (ILD) 48 and CESL 46 as shown in FIGS. 5A and 5B. Accordingly, in FIG. 4B, source/drain silicide regions 144 and 244 are illustrated using dashed lines to indicate they may or may not be formed at this time. In subsequent drawings, source/drain silicide regions 144 and 244 are not illustrated.

Contact Etch Stop Layer (CESL) 46 and Inter-Layer Dielectric (ILD) 48 are then formed, as shown in FIGS. 5A and 5B, which illustrate a perspective view and a cross-sectional view, respectively. The respective step is illustrated as step S308 in the process flow shown in FIG. 19. CESL 46 and ILD 48 may extend to a level lower than bottom surfaces of epitaxy regions 140 and 240. CESL 46 may be formed of SiN, SiCN, SiOC, SiON, SiCN, SiOCN, or the like. In accordance with some embodiments of the present disclosure, CESL 46 may include or may be free from oxygen therein. CESL 46 may be formed using a conformal deposition method such as ALD or CVD, for example. ILD 48 may include a dielectric material formed using, for example, FCVD, spin-on coating, CVD, or another deposition method. ILD 48 may also be formed of an oxygen-containing dielectric material, which may be silicon-oxide (SiO) based or silicon-oxycarbide (SiOC) based such as Tetra Ethyl Ortho Silicate (TEOS) oxide, Plasma-Enhanced CVD (PECVD) oxide (SiO2), Phospho-Silicate Glass (PSG), Boro-Silicate Glass (BSG), Boron-Doped Phospho-Silicate Glass (BPSG), or the like. A planarization step such as Chemical Mechanical Polish (CMP) or mechanical grinding may be performed to level the top surfaces of ILD 48, dummy gate stacks 130 and 230, and gate spacers 138 and 238 with each other.

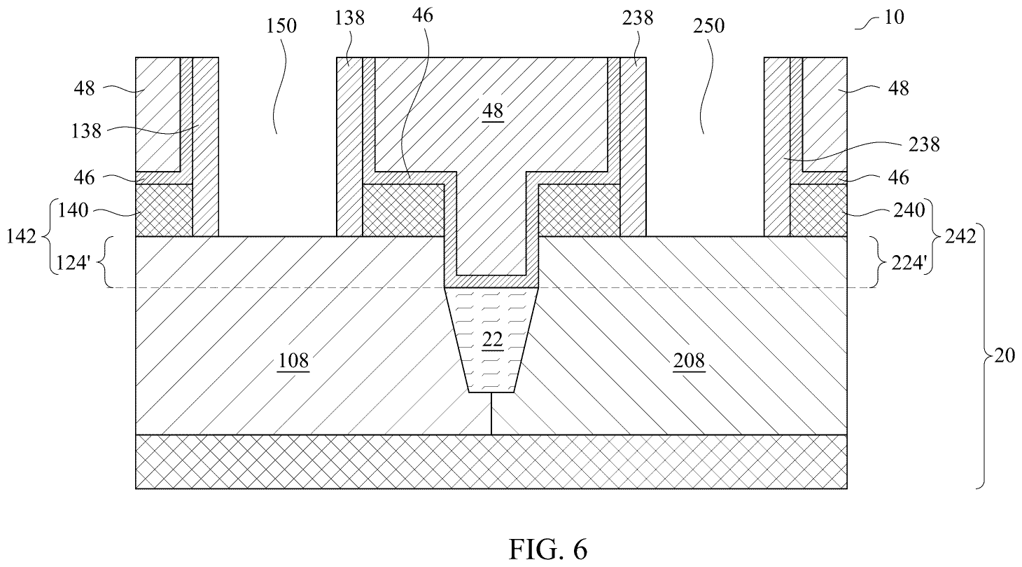

Next, dummy gate stacks 130 and 230, which include hard mask layers 136 and 236, dummy gate electrodes 134 and 234, and dummy gate dielectrics 132 and 232, are removed, forming openings 150 and 250, respectively, as shown in FIG. 6. The respective step is illustrated as step S310 in the process flow shown in FIG. 19. The surfaces of protruding fins 124′ and 224′ are exposed. FIG. 6 illustrates the exposure of the top surfaces of protruding fins 124′ and 224′. The sidewalls surfaces of protruding fins 124′ and 224′ are also exposed to openings 150 and 250. Next, a cleaning step is performed to clean the surfaces of protruding fins 124′ and 224′ to remove native oxide. The cleaning may be performed, for example, using diluted HF solution.

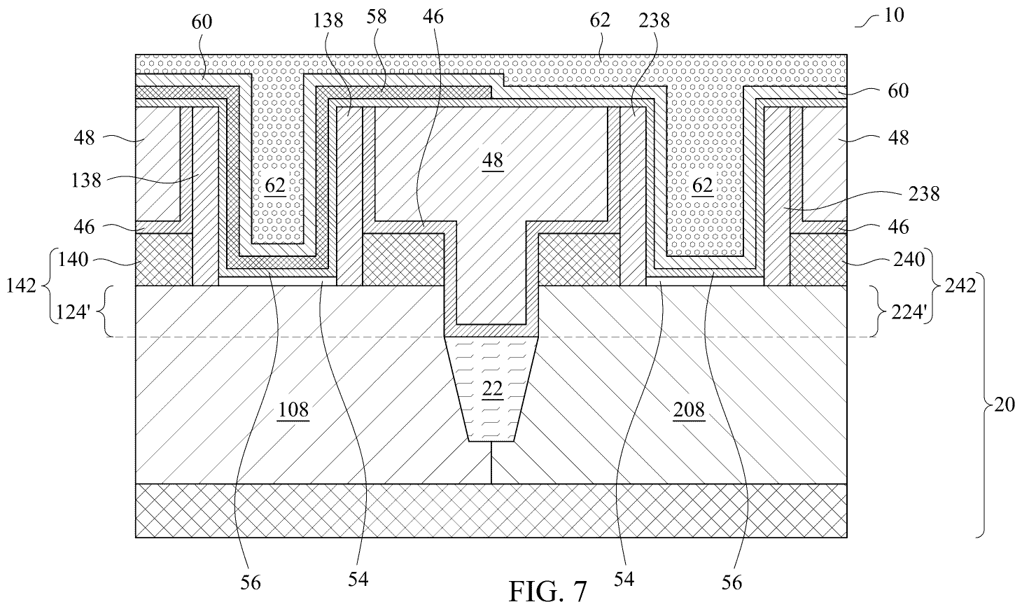

FIG. 7 illustrates a plurality of layers for forming replacement gates. The respective step is illustrated as step S312 in the process flow shown in FIG. 19.

Interfacial Layer (IL) 54, which includes silicon oxide such as SiO2, is formed. In accordance with some embodiments of the present disclosure, IL 54 is a chemical oxide layer formed by substrate 20 in a mixture of NH4OH and H2 O2 (and/or H2O), a mixture of HCl and H2 O2 (and/or H2O), a mixture of H2SO4 and H2O2, or the like. Through the chemical treatment, silicon oxide is formed on the surfaces of protruding fins 124′ and 224′ due to the reaction of the surface material of protruding fins 124′ and 224′ with the chemical solution. The thickness of IL 54 may be in the range between about 0.2 nm and about 2 nm. In accordance with some embodiments of the present disclosure, the treatment using the chemical solution is performed ex-situ with the subsequent formation of high-k gate dielectric.

Next, high-k gate dielectric 56 is formed. In accordance with some embodiments of the present disclosure, high-k gate dielectric 56 includes high-k dielectric materials such as HfO2, ZrO2, HfZrOx, HfSiOx, HfSiON, ZrSiOx, HfZrSiOx, Al2O3, HfAlOx, HfAlN, ZrAlOx, La2O3, TiO2, Yb2O3, or the like. High-k gate dielectric 56 may be a single layer or a composite layer including more than one layer. In accordance with some exemplary embodiments, the formation is performed using a process gas including HfCl4 and O3.

Stacked layers 58 and 60 are deposited. Each of the stacked layers 58 and 60 may include a plurality of sub-layers. The sub-layers in stacked layers 58 and 60 are not shown separately, while the sub-layers may be distinguishable from each other. The deposition may be performed using conformal deposition methods such as ALD or CVD, so that the thicknesses of the vertical portions and the thicknesses of the horizontal portions of stacked layers 58 and 60 (and each of sub-layers) are substantially equal to each other. Stacked layers 58 and 60 include some portions over ILD 48.

Each of stacked layers 58 and 60 may include a diffusion barrier layer and one (or more) work-function layer over the diffusion barrier layer. The diffusion barrier layer may be formed of titanium nitride (TiN), which may (or may not) be doped with silicon. The work-function layer determines the work function of the respective gate, and includes at least one layer, or a plurality of layers formed of different materials. The material of the work-function layer is selected according to whether the respective FinFET is an n-type FinFET or a p-type FinFET. For example, for the p-type FinFET formed in device region 100, the work-function layer in stacked layer 58 may include Ti, Al, TiAl, TiAlN, Ta, TaN, TiAlC, TaAlCSi, TaAlC, TiSiN, or the like. An exemplary stacked work function layer in layer 58 includes a TaN layer, a TiN layer over the TaN layer, and a TiAl layer over the TiN layer. For the n-type FinFET formed in device region 200, the work-function layer in stacked layer 60 may include TiN, TaN, TiAl, W, Ta, Ni, Pt, or the like. An exemplary stacked work function layer in layer 60 includes a TaN layer and a TiAl layer over the TaN layer. After the deposition of the work-function layer(s), a barrier layer, which may be another TiN layer, is formed, which layer is included in stacked layer 60 in an exemplary embodiment.

In the exemplary embodiment as shown in FIG. 7, the formation process of stacked layers include blanket depositing stacked layers 58, which includes work function metals for p-type transistors, patterning stacked layers 58 to remove the portions in device region 200, and then blanket depositing stacked layers 60, so that stacked layers 60 have portions overlapping stacked layers 58. The work function of the transistor in device region 100 is mainly determined by stacked layers 58, and the work function of the transistor in device region 200 is mainly determined by stacked layers 60.

Next, as also shown in FIG. 7, metallic material 62 is deposited, which may be formed of tungsten, cobalt, copper, ruthenium, aluminum, or the like. Metallic material 62 fully fills remaining openings 150 and 250 (FIG. 5) .

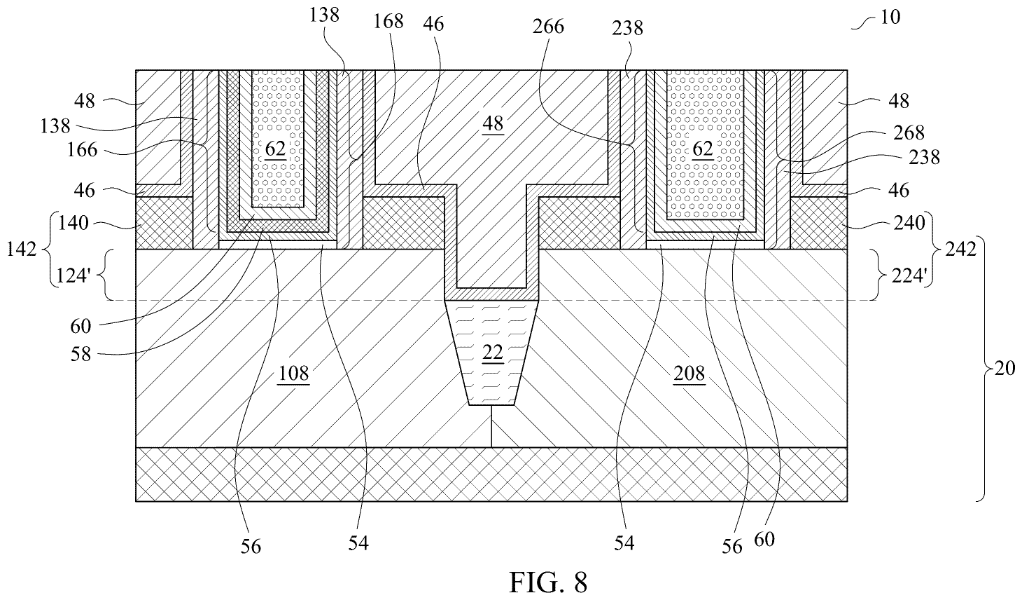

In a subsequent step as shown in FIG. 8, a planarization step such as CMP or mechanical grinding is performed, so that the portions of layers 58, 60, and 62 over ILD 48 are removed. As a result, replacement metal gate electrodes 166 and 266 are formed, which include the remaining portions of layers 58, 60, and 62. The respective step is illustrated as step S314 in the process flow shown in FIG. 19. Replacement metal gate electrodes 166 and 266 in combination with the underlying IL 54 and high-k gate dielectric 56 are referred to as replacement gate stacks 168 and 268, respectively.

FIG. 9 illustrate the recessing of gate stacks 168 and 268, which is performed through etching gate electrodes 166 and 266 and the high-k dielectric layers 56. The respective step is illustrated as step S316 in the process flow shown in FIG. 19. Recesses 70 are thus formed. In accordance with some embodiments of the present disclosure, recesses 70 have depths in the range between about 0.5 μm and about 10 μm.

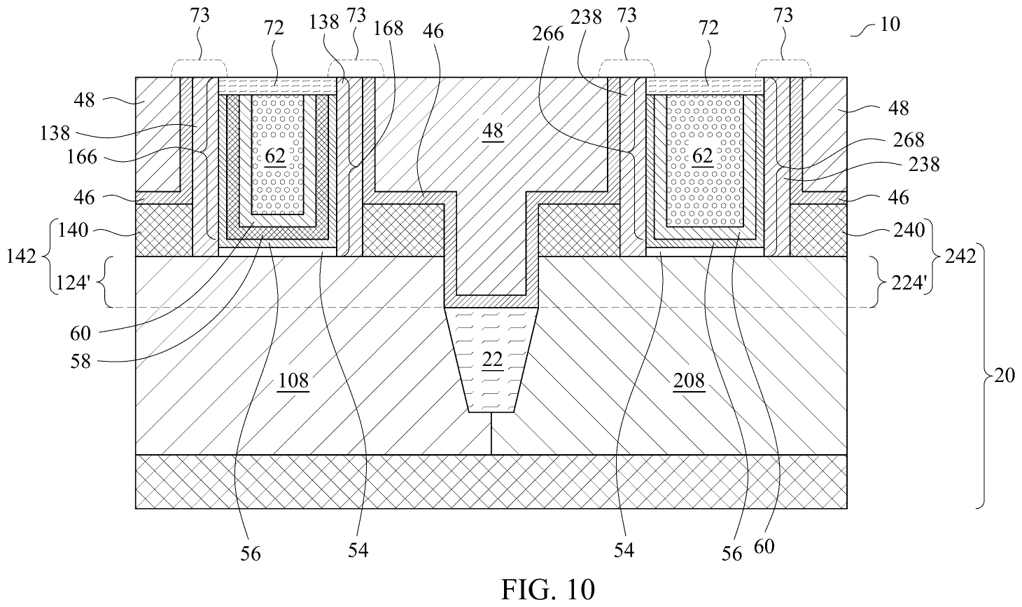

FIG. 10 illustrates the selective formation of inhibitor films 72. The respective step is illustrated as step S318 in the process flow shown in FIG. 19. In accordance with some embodiments of the present disclosure, inhibitor films 72 are formed through selective deposition. The deposition methods may include Plasma Enhanced Chemical Vapor Deposition (PECVD), Chemical Vapor Deposition (CVD), or the like. Inhibitor films 72 may include plasma-polymerized fluorocarbon. The plasma-polymerized fluorocarbon includes carbon and fluorine. In accordance with some embodiments, the precursor for forming inhibitor films 72 include a mixture of CF4 and C4H8, and the resulting inhibitor films 72 are formed of a polymer using plasma. The carbon percentage in inhibitor films 72 may be in the range between about 30 percent and about 80 percent. Since the materials of gate spacers 138 and 238, CESL 46, and ILD 48 are different from that of gate stacks 168 and 268, the deposition is selective, and inhibitor films 72 are grown from gate stacks 168 and 268, and not from ILD 48. Inhibitor films 72 may, or may not, have extended portions grown on high-k dielectrics 56, gate spacers 138 and 238 and CESL 46. For example, when gate spacers 138 and 238 are formed of silicon oxide, and CESL 46 is formed of silicon oxide and/or silicon nitride, inhibitor films 72 are also grown on gate spacers 138 and 238 and CESL 46. The dashed lines 73 schematically illustrate the corresponding extended portions of inhibitor films 72. The thickness of inhibitor films 72 may be greater than about 10 nm, and may be in the range between about 10 nm and about 100 nm. The top surfaces of inhibitor films 72 may be lower than, level with, or higher than the top surfaces of ILD 48.

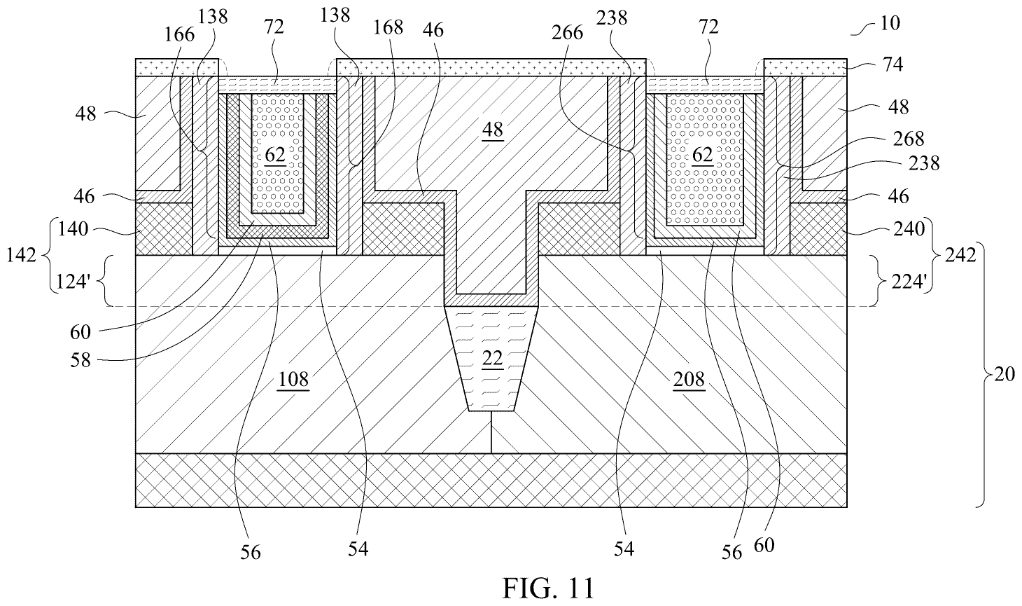

FIG. 11 illustrates the formation of dielectric hard mask 74, which is selectively grown on the exposed surfaces that are not protected by inhibitor films 72. The respective step is illustrated as step S320 in the process flow shown in FIG. 19. In accordance with some embodiments of the present disclosure, dielectric hard mask 74 is formed of a metal oxide. For example, dielectric hard mask 74 may be formed of ZrO2, HfO2, Y2O3, HfZrOx, hafnium silicate (HfSiOx), zirconium silicate (ZrSiOx), yttrium silicates (YSiOx), HfZrSiOx, Al2O3, HfAlOx, ZrAlOx, La2O3, lanthanum silicate (LaSiOx), ZnO, TiO2, or combinations thereof. The deposition method may include Atomic Layer Deposition (ALD), PECVD, CVD, or the like. Inhibitor films 72 prohibit the growth of dielectric hard mask 74 thereon. However, due to the lateral growth of dielectric hard mask 74, dielectric hard mask 74 may have some small edge portions overlapping the edges of inhibitor films 72 slightly, which is also shown by dashed lines. Dielectric hard mask 74 may have a thickness in the range between about 3 nm and about 30 nm, for example.

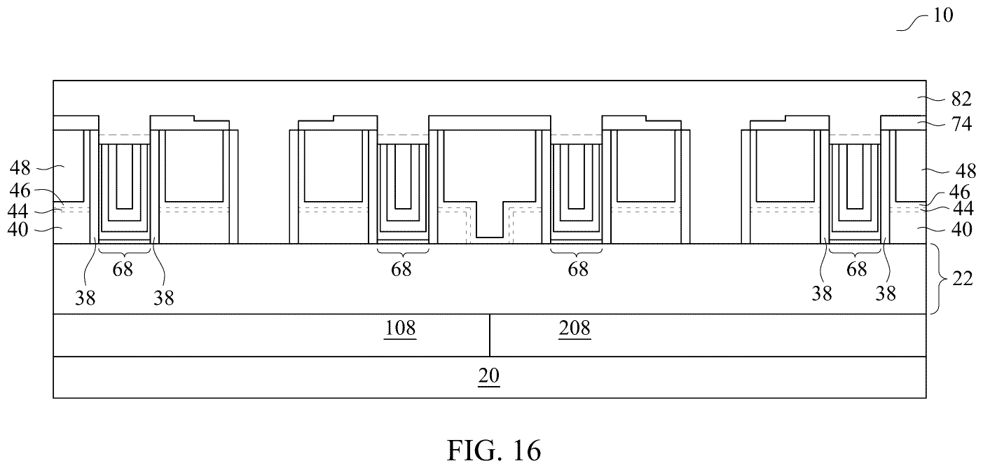

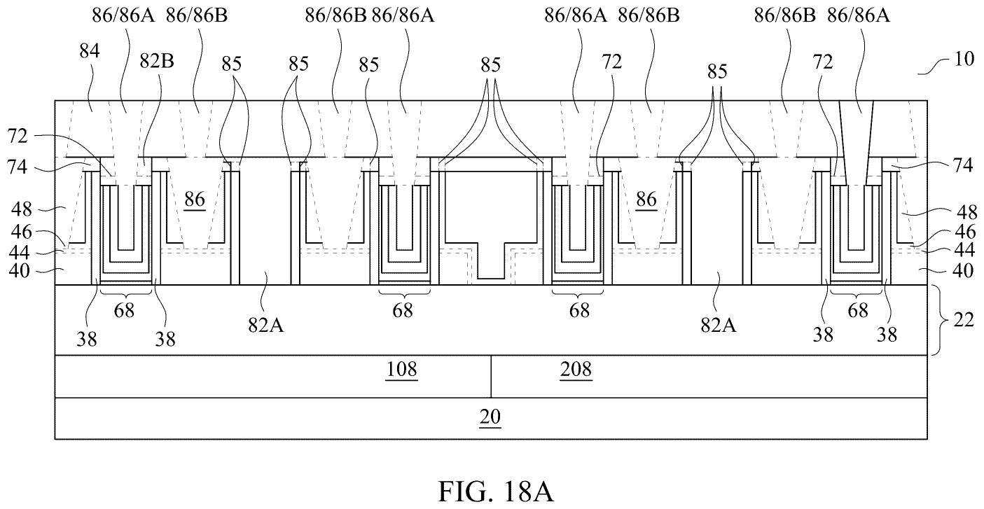

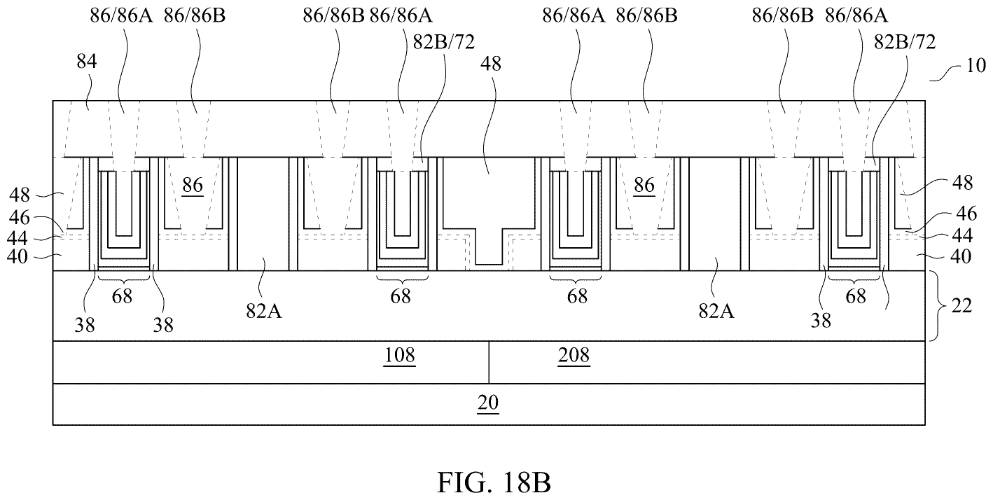

Inhibitor films 72 are then removed in accordance with some embodiments of the present disclosure, as shown FIG. 12. The respective step is illustrated as step S322 in the process flow shown in FIG. 19. In accordance with alternative embodiments, inhibitor films 72 are not removed at this stage. Rather, it is removed before the isolation layer 82 as shown in FIG. 16 is deposited. In accordance with yet other embodiments, inhibitor films 72 are not removed, and will remain in the final structure, with gate contact plugs 86 (FIG. 18A) penetrating through inhibitor films 72. In accordance with some embodiments of the present disclosure, inhibitor films 72 are removed through plasma ashing using O2 or a mixture of H2 and N2 as process gases.

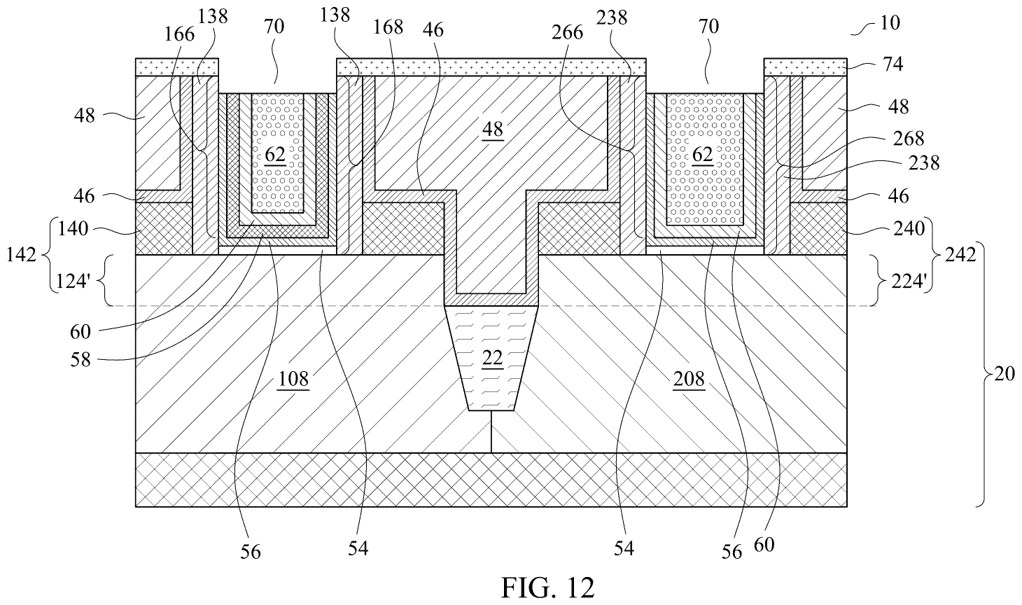

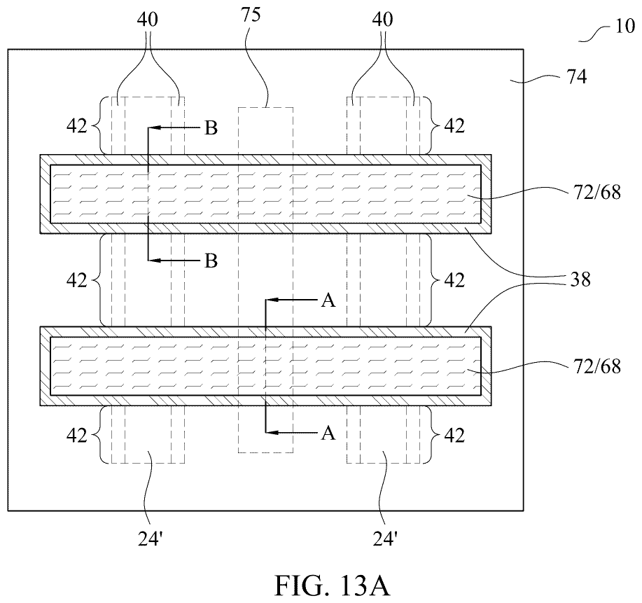

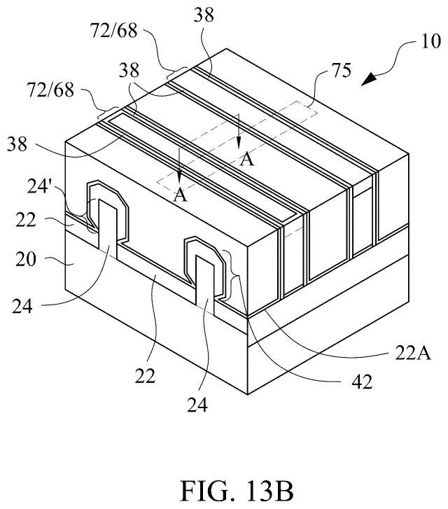

In subsequent steps, a cut-metal-gate process is performed, so that long metal gates 166 and 266 are cut into a plurality of electrically disconnected portions, and each may be used as a metal gate of one or more FinFET. For example, FIG. 13A illustrates two gate stacks 68, with each representing either 168 or 268 as in FIG. 12. Inhibitor films 72 are formed overlapping gate stacks 68. Dielectric hard mask 74 may cover all illustrated regions in FIG. 13A except the regions in which inhibitor films 72 are formed. Two protruding active regions or fins 24′ (with each being either 124′ or 224′ in FIG. 12) are crossed over by gate stacks 68. Protruding fins 24′ are the top portions of semiconductor strips 24 (with each being either 124 or 224 in FIG. 5A). Epitaxy regions 40 (which may be 140 or 240 in FIG. 12) , gate spacers 38 (which may be 138 or 238 in FIG. 12) , and source/drain regions 42 (which may be 142 or 242 in FIG. 12) are also illustrated. In accordance with some embodiments of the present disclosure, the portions of gate stacks 68 inside dashed region 75 are to be removed, and are replaced with a dielectric material. The portions of gate stacks 68 on the left side and the right side of region 75 are not removed, and will form the gate stacks of a FinFET(s) on the left side and a FinFET(s) on the right side of region 75. FIG. 13B illustrates a perspective view of the structure shown in FIG. 13A, wherein region 75 is illustrated, and the portions of gate electrodes 68 in region 75 will be removed in subsequent cut-metal-gate process.

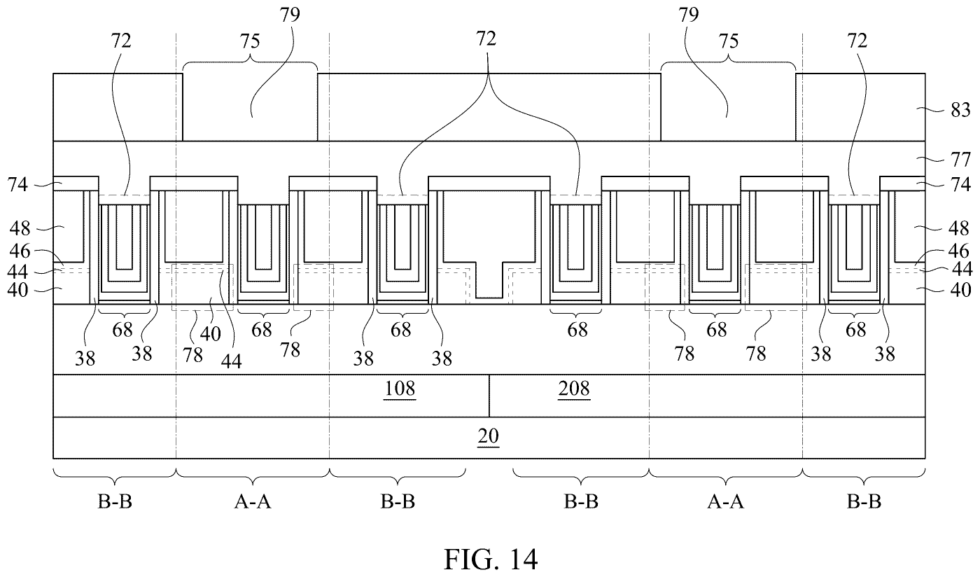

FIG. 14 illustrates the formation of Bottom Anti-Reflective Coating (BARC) 77 and photo resist 83 on the structure formed in preceding steps. The respective step is illustrated as step S324 in the process flow shown in FIG. 19. It is noted that the cross-sectional view shown in FIG. 14 is not obtained from a single plane in FIG. 13A. Rather, it combines the views from several regions in FIG. 13A. For example, the regions marked as A-A in FIG. 14 may be obtained from the plane containing line A-A in FIG. 13A, and the portions marked as B-B in FIG. 14 may be obtained from the plane containing line B-B in FIG. 13A. Furthermore, although n-well region 108 and p-well region 208 are illustrated as appearing in regions A-A, STI regions 22 (which are shown as being dashed) may be in regions A-A rather than having well regions. Also, epitaxy regions 40 and silicide regions 44 (representing regions 144 and/or 244) may exist in regions 78 when regions 78 are in regions B-B in accordance with some embodiments of the present disclosure, as illustrated, and well regions 108 and 208 extend up to the epitaxy regions 40. On the other hand, no epitaxy regions 40 and silicide regions 44 are in regions 78 when regions 78 are in regions A-A), and CESL 46 may extend down to contact STI region 22. It is noted that the discussion of dashed regions 78 and the dashed STI regions 22 as shown in FIG. 14 may also apply to all subsequently illustrated figures that combine regions A-A and B-B, and the respective discussion is not repeated herein.

As shown in FIG. 14, photo resist 83 is patterned to form opening 79. Referring to FIGS. 13A and 13B, opening 79 may be at the same position, and has the same size, as region 75, while the regions surrounding region 75 are covered by photo resist 83.

Next, the portions of gate stacks 68 exposed to openings 79 are etched, forming openings 80 extending between gate spacers 38. The resulting structure is shown in FIG. 15. The respective step is illustrated as step S326 in the process flow shown in FIG. 19, and the respective process is referred to as a cut-metal-gate process. In accordance with some embodiments of the present disclosure, the etching comprises dry etching using chlorine-containing or fluorine-containing gases, which may include Cl2, NF3, SiCl4, BCl3, O2, N2,H2, Ar, or the mixtures of some of these gases.

In a subsequent step, photo resist 83 and BARC 77 are removed. If inhibitor films 72 remain over gate stacks 68 at this time, inhibitor films 72 may be removed, or may be left unremoved. In the cut-metal-gate process, dielectric hard masks 74 protects the underlying ILD 48, so that the opening does not extend into ILD. As a comparison, if dielectric hard masks 74 are not formed, openings 81 may adversely extend into ILD 48.

Referring to FIG. 16, isolation layer 82 is deposited to fill openings 80 as shown in FIG. 15, which shows a cross-section A-A in FIG. 13A. It is appreciated that epitaxy regions 40 and source/drain silicide regions 44 are in cross-section B-B (FIG. 13) , and are not in the illustrated cross-section A-A. Accordingly, epitaxy regions 40 and source/drain silicide regions 44 are illustrated as being dashed. The respective step is illustrated as step S328 in the process flow shown in FIG. 19. In accordance with some embodiments of the present disclosure, isolation layer 82 is formed of SiO, SiN, SiC, SiCN, SiOC, SiON, SiOCN, or the like. The deposition method may include PECVD, ALD, CVD, or the like. Isolation layer 82 is deposited to a level higher than the top surface of dielectric hard mask 74.

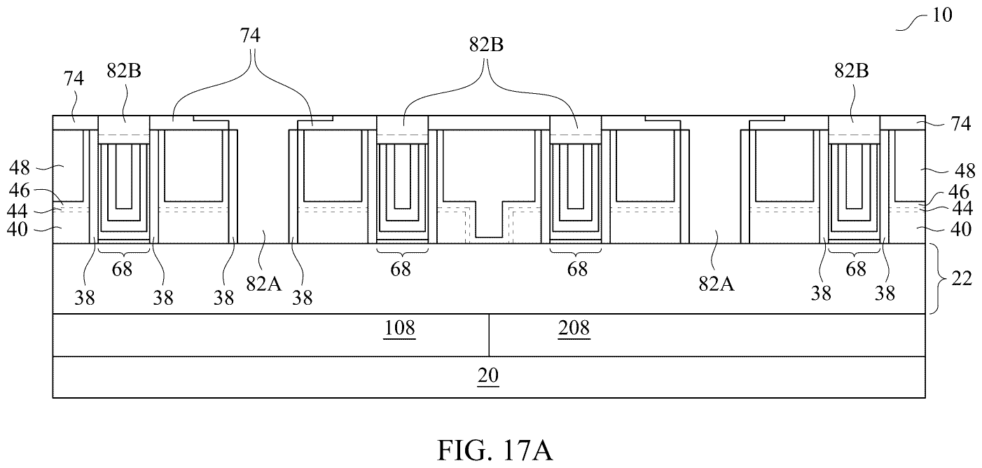

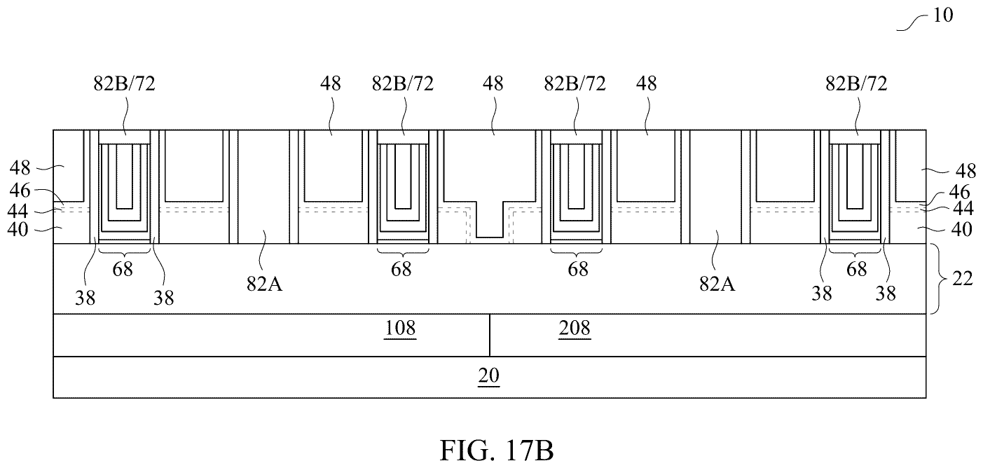

Referring to FIG. 17A, a planarization process such as a Chemical Mechanical Polish (CMP) process is performed. The respective step is illustrated as step S330 in the process flow shown in FIG. 19. The slurry used for the CMP may include silica or ceria, or may be an alumina-abrasive-based slurry. Dielectric hard mask 74 is used as a CMP stop layer. The resulting structure includes insulation features 82A and gate hard masks 82B.

Referring back to FIG. 17A, dielectric hard mask 74 may cover the portions of replacement gate stacks 68 on the opposite sides of insulation features 82A. Dielectric hard mask 74 may, or may not, extend on gate spacers 38, and may or may not further extend on CESL 46 (not shown in FIG. 44) . Gate hard masks 82B extend between gate spacers 38, and may have a thickness in the range between about 20 nm and about 200 nm.

FIG. 18A illustrates the formation of Inter-Metal Dielectric (IMD) 84 and contact plugs 86 in accordance with some embodiments. The respective step is illustrated as step S332 in the process flow shown in FIG. 19. IMD 84 may have a thickness in the range between about 10 nm and about 50 nm, and may be formed of SiO, SiN, SiC, SiCN, SiOC, SiON, or SiOCN. Contact plugs 86 include gate contact plugs 86A and source/drain contact plugs 86B. It is appreciated that source/drain contact plugs 86B are in cross-section B-B (FIG. 13), and are not in the illustrated cross-section A-A. Accordingly, source/drain contact plugs 86B are illustrated as being dashed. Contact plugs 86 may be formed of W, Co, Ru, or Cu, and may or may not include a conductive barrier layer formed of titanium nitride, tantalum nitride, or the like. If inhibitor films 72 remain at this stage, gate contact plugs 76 will penetrate through inhibitor films 72.

Since dielectric hard mask 74 may or may not extend directly over CESL 46 and/or gate spacers 38, FIG. 18A illustrates dashed lines 85 to show the likely positions of the edges of dielectric hard mask 74 in accordance with various embodiments. It is appreciated that if dielectric hard mask 74 does not extend on CESL 46 and/or gate spacers 38, gate hard masks 82B will extend on CESL 46 and/or gate spacers 38. Furthermore, dashed lines 85 are also shown in FIGS. 27A, 35, and 43A to indicate the possible positions of the edges of dielectric hard mask 74 in accordance with some other embodiments.

FIG. 17B illustrates the planarization process in accordance with alternative embodiments. Dielectric hard mask 74 as shown in FIG. 16 is fully removed in the planarization process, and ILD 48 is exposed. Accordingly, no dielectric hard mask 74 is left. FIG. 18B illustrates the respective IMD 84 and contact plugs 86. The illustrated regions directly over gates 68 may include gate hard masks 82B, inhibitor films 72, or composite layers including inhibitor films 72 and gate hard masks 82B over inhibitor films 72.

Embodiments herein provide cut metal gate insulation features 500 with structures to reduce electrical leakage. For example, embodiments herein may prevent substrate leakage from NMOS to PMOS by forming the structure of the cut metal gate insulation features 500 that does not extend into the semiconductor substrate 200.

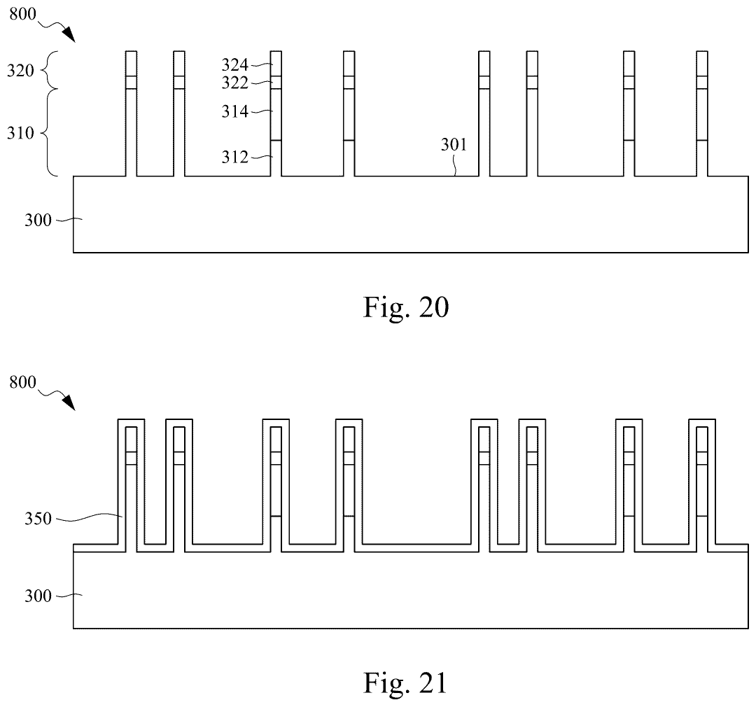

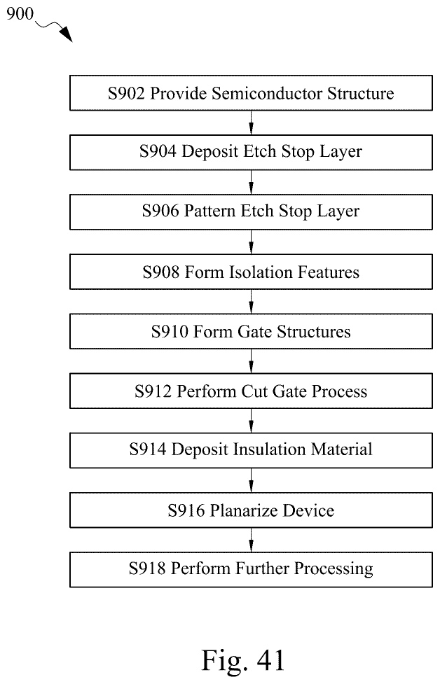

FIGS. 20-30 illustrate method steps for forming a device 800 with such cut metal gate insulation features 500. Method 900 is illustrate in the flow chart of FIG. 41.

For example, FIG. 20 illustrates that the method 900 may provide, at S902, a structure 10 including a substrate 300 formed with protruding active regions or fins 310, such as according to method steps above. As shown, the fins 310 extend upward from an upper surface of the semiconductor substrate 300.

Fins 310 may include a silicon layer 312 and a silicon germanium layer 314.

Further, masks 320 may be located over the fins 310. Masks 320 may include a silicon oxide mask layer 322 and a silicon nitride mask layer 324.

In FIG. 21, method 900 may continue at S904 with depositing an etch stop layer 350 over the device 800. As shown, the etch stop layer 350 is deposited directly onto the upper surface 301 of the semiconductor substate 300.

Etch stop layer 350 may be formed of SiN, SiCN, SiOC, SiON, SiCN, SiOCN, any non-fix charge film, any high etch selectivity film (such as with respect to the STI oxide material) including SiC, SiOC, SiOCN, SiGe, TiN, or other suitable high etch selectivity film, or the like. In accordance with some embodiments of the present disclosure, etch stop layer 350 may include or may be free from oxygen therein. Etch stop layer 350 may be formed using a conformal deposition method such as ALD or CVD.

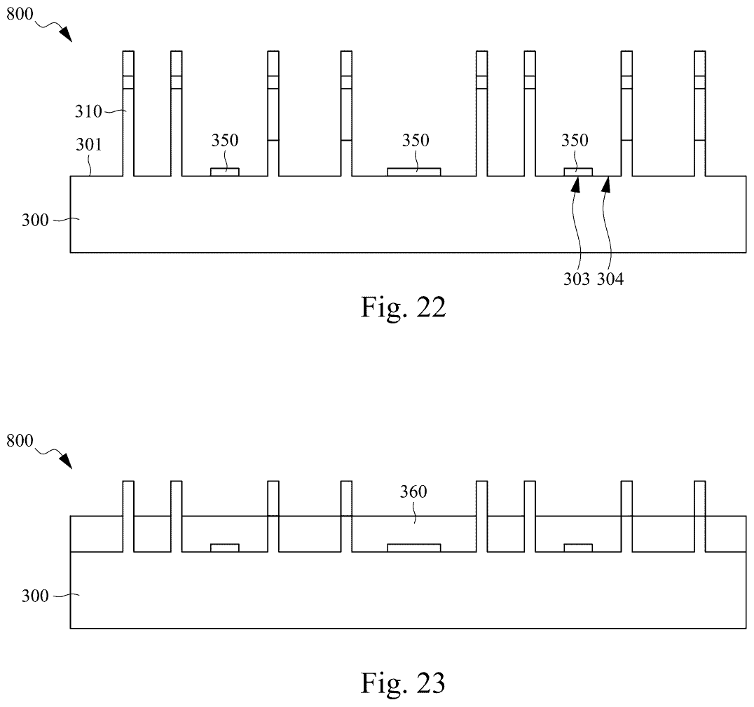

Method 900 may continue at S906 with patterning the etch stop layer 350, at shown in FIG. 22. As a result, segments of the etch stop layer 350 cover covered regions 303 of the upper surface 301 of the semiconductor substrate 300, while uncovered regions 304 of the upper surface 301 of the semiconductor substrate 300 are not covered by the etch stop layer 350.

As shown, segments of the etch stop layer 350 may not contact the fins 310. Further, as described below, the segments of the etch stop layer 350 may be located over interfaces between N-wells and P-wells formed in the semiconductor substrate 300.

Method 900 continues at S908 with forming isolation features 360 over the semiconductor substrate 300 and between the fins 310 as shown in FIG. 23. For example, a Shallow Trench Isolation (STI) features 360 may be formed. STI features 360 may include a liner oxide (not shown). The liner oxide may be formed of a thermal oxide formed through a thermal oxidation of a surface layer of substrate 20. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). STI features 360 may also include a dielectric material over the liner oxide, and the dielectric material may be formed using Flowable Chemical Vapor Deposition (FCVD), spin-on coating, or the like.

As shown in FIG. 23, STI features 360 are recessed, so that the top portions of fins 310 protrude higher than the top surfaces of the neighboring STI features 360. The etching may be performed using a dry etching process, wherein NH3 and NF3 are used as the etching gases. During the etching process, plasma may be generated. Argon may also be included. In accordance with alternative embodiments of the present disclosure, the recessing of STI features 360 is performed using a wet etch process. The etching chemical may include diluted HF, for example.

As shown, the STI features 360 contact the upper surface 301 of the semiconductor substrate 300 in uncovered regions 304. In covered regions 303, the segments of etch stop layer 350 are interposed between the STI features 360 and the upper surface 301 of the semiconductor substrate 300.

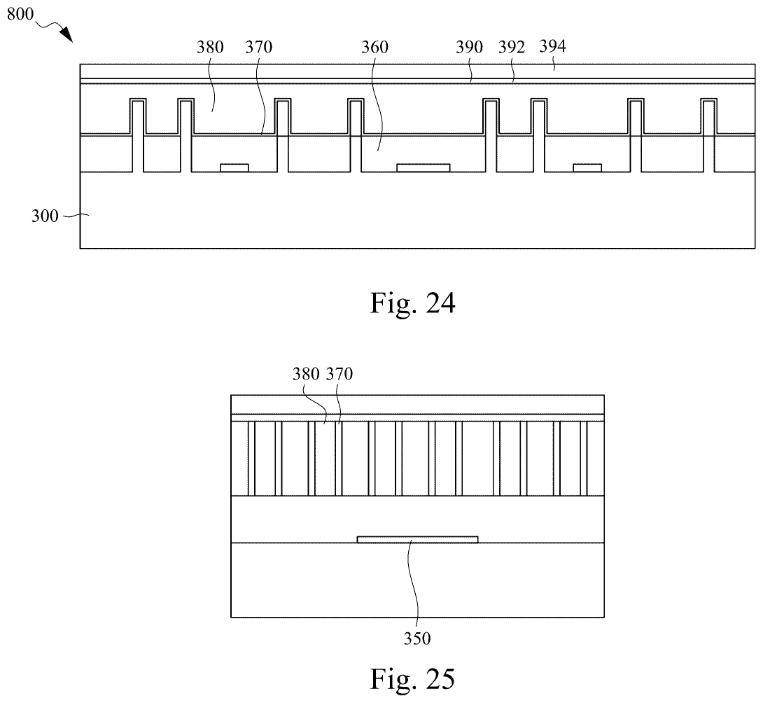

Method 900 may include further processing at S910, as described above, including formation of dummy gate stacks, formation of source/drain features, and formation of replacement metal gates. As a result, the device 800 as shown in FIG. 24 includes a gate dielectric layer 370, such as a high-k gate dielectric, overlying the fins 310 and STI features 360; a metal gate electrode 380 overlying the gate dielectric layer 370; and a mask 390 overlying the metal gate electrode 380. The mask 390 may include a mask layer 392, such as titanium nitride, and a mask layer 394, such as silicon nitride.

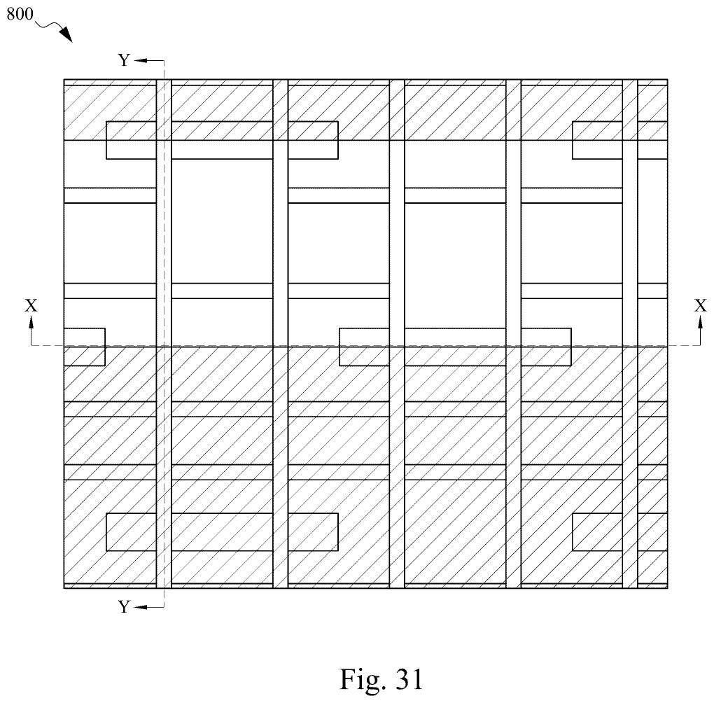

FIG. 25 illustrates the device 800, at the stage of fabrication of FIG. 24, along an X-cut passing through a metal gate, such as along line X-X in FIG. 31. As shown, two parallel gate structures, including gate dielectric layers 370 and metal gate electrodes 380, are formed on the STI feature 360 directly over the segment of etch stop layer 350.

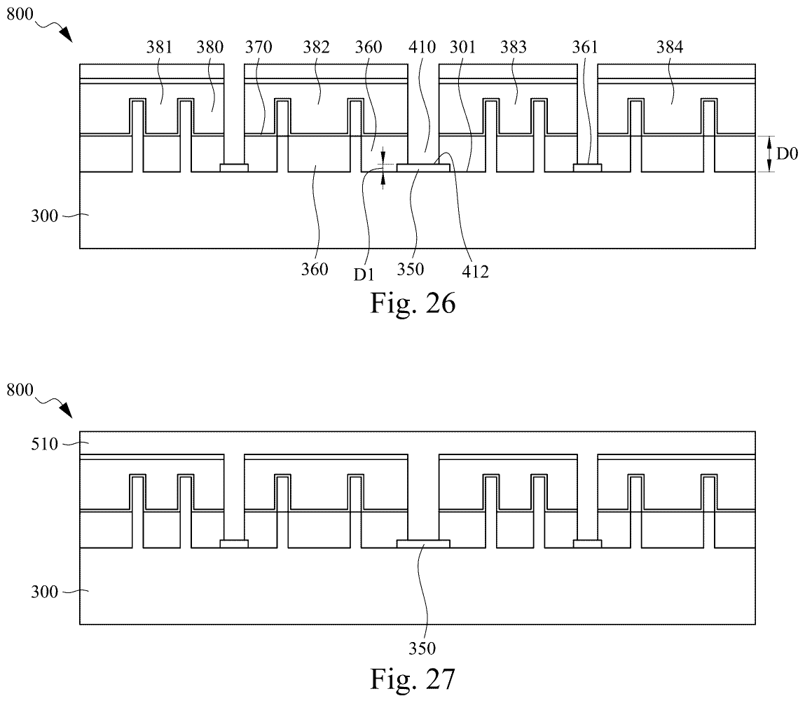

Method 900 continues at S912 as shown in FIG. 26 with performing a cut-gate or cut-metal-gate process as described above, to separate the metal gate electrode 380 into discrete metal gate segments, such as segments 381, 382, 383, and 384. These metal gate segments may be used as a metal gate of one or more FinFET.

As shown in FIG. 26, the etch process includes etching through the metal gate electrode 380, through the gate dielectric 370 and through the STI feature 360. The etch process lands on the etch stop layer segment 350. The etch process forms a trench 410. The trench 410 has a bottom surface 412. In FIG. 25, the trench bottom surface 412 is formed by an upper surface 361 of the STI feature 360. Further the trench bottom surface 412 is distanced from the upper surface 301 of the semiconductor substrate 300 by a distance D1. In FIG. 25, distance D1 is equal to the vertical thickness of the etch stop layer segment 350.

As shown, the STI feature 360 has a maximum vertical thickness or distance D0, such as from the interface with the substrate to the interface with the gate dielectric layer 370. In certain embodiments, distance D1 is at least 5% of distance D0. For example, distance D1 may be at least 10%, at least 15%, at least 20%, at least 25%, at least 30%, at least 35%, at least 40%, or at least 45% of distance D0. In certain embodiments, distance D1 is at most 60% of distance D0, for example, distance D1 may be at most 55%, at most 50%, at most 45%, at most 40%, at most 35%, at most 30%, at most 25%, at most 20%, at most 15%, at most 10%, or at most 5% of distance D0.

As shown in FIG. 27, method 900 continues at S914 with depositing an insulation material 510. As shown, the insulation material 510 fills the trench 410. In accordance with some embodiments of the present disclosure, insulation material is SiO, SiN, SiC, SiCN, SiOC, SiON, SiOCN, or the like. The deposition method may include PECVD, ALD, CVD, or the like. Insulation material 510 is deposited to a level higher than the top surface of mask 390.

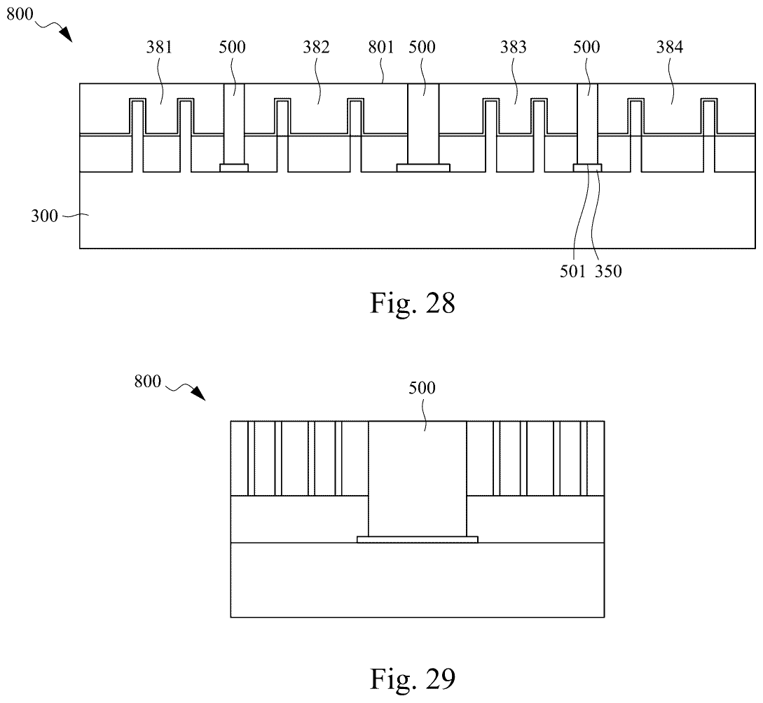

Method 900 may continue at S916 with planarizing the device 800 to remove the overburden portion of the insulation material 510 and the mask 390, and to define the cut metal gate insulation features 500 between the gate segments 381, 382, 383, and 384 as shown in FIG. 28.

FIG. 29 illustrates the device 800, at the stage of fabrication of FIG. 28, along an X-cut passing through a metal gate, such as along line X-X in FIG. 31. As shown, two parallel gate structures are cut and replaced with the cut metal gate insulation feature 500.

Cross-referencing FIGS. 28 and 29, after planarizing the device 800, the device 800 has a top surface 801 defined by the cut metal gate insulation features 500 and gate segments 381, 382, 383, and 384.

As shown, each cut metal gate insulation feature 500 has a bottom surface 501. In the embodiment of FIG. 28, the bottom surface 501 is planar or substantially planar. In the embodiment of FIG. 28, the bottom surface 501 contacts the etch stop layer 350. In the embodiment of FIG. 28, the etch stop layer 350 does not contact the fins 310.

Method 900 may further include performing further processing at S918. For example, metallization and dielectric layers may be depositing and patterned to form contacts and electrical connections as desired.

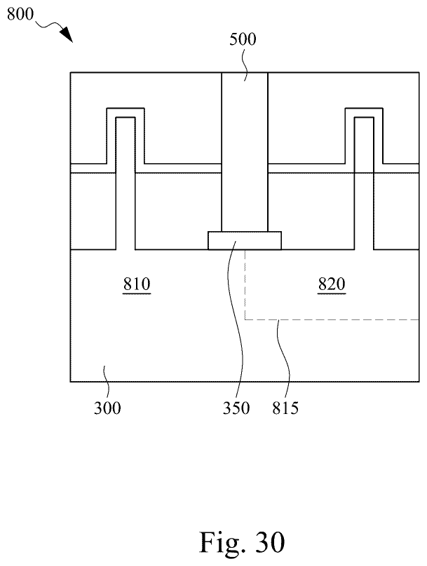

FIG. 30 illustrates a portion of the device 800 of FIG. 28. As shown, the cut metal gate insulation feature 500 lies directly over a vertical interface 815 between a well 810 of a first type of conductivity and a well 820 of a second type of conductivity. For example well 810 may be a P-well and well 820 may be an N-well.

FIG. 31 illustrates a overhead layout view of the device 800 of FIGS. 28 and 29. The cross-sectional views of FIGS. 20-24 and 26-28 are taken along line Y-Y in FIG. 31. The cross-sectional views of FIGS. 25 and 29 are taken along line X-X in FIG. 31.

FIGS. 20-30 illustrate an embodiment in which an etch stop layer separates the cut metal gate insulation features 500 from the upper surface 301 of the semiconductor substrate 300. In other embodiments, the etch stop layer 350 is not present.

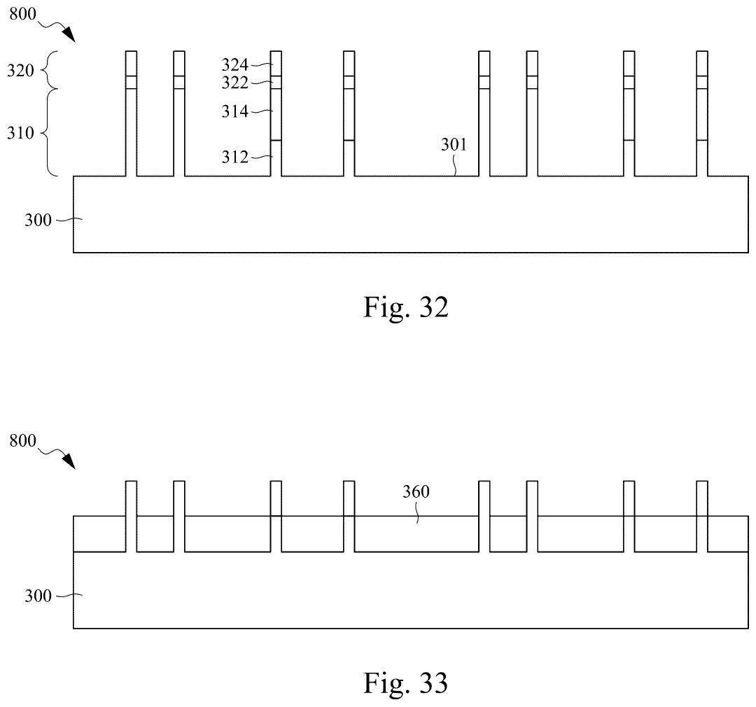

For example, as shown in FIG. 32, method 900 may provide, at S902, a structure 10 including a substrate 300 formed with protruding active regions or fins 310, such as according to method steps above. As shown, the fins 310 extend upward from an upper surface of the semiconductor substrate 300.

Fins 310 may include a silicon layer 312 and a silicon germanium layer 314.

Further, masks 320 may be located over the fins 310. Masks 320 may include a silicon oxide mask layer 322 and a silicon nitride mask layer 324.

In FIG. 33, method 900 may continue at S908 with forming isolation features 360 over the semiconductor substrate 300 and between the fins 310 as shown in FIG. 23. For example, a Shallow Trench Isolation (STI) features 360 may be formed. STI features 360 may include a liner oxide (not shown). The liner oxide may be formed of a thermal oxide formed through a thermal oxidation of a surface layer of substrate 20. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). STI features 360 may also include a dielectric material over the liner oxide, and the dielectric material may be formed using Flowable Chemical Vapor Deposition (FCVD), spin-on coating, or the like.

As shown in FIG. 33, STI features 360 are recessed, so that the top portions of fins 310 protrude higher than the top surfaces of the neighboring STI features 360. The etching may be performed using a dry etching process, wherein NH3 and NF3 are used as the etching gases. During the etching process, plasma may be generated. Argon may also be included. In accordance with alternative embodiments of the present disclosure, the recessing of STI features 360 is performed using a wet etch process. The etching chemical may include diluted HF, for example. As shown, the STI features 360 contact the upper surface 301 of the semiconductor substrate 300.

Method 900 may include further processing at S910, as described above, including formation of dummy gate stacks, formation of source/drain features, and formation of replacement metal gates. As a result, the device 800 as shown in FIG. 24 includes a gate dielectric layer 370, such as a high-k gate dielectric, overlying the fins 310 and STI features 360; a metal gate electrode 380 overlying the gate dielectric layer 370; and a mask 390 overlying the metal gate electrode 380. The mask 390 may include a mask layer 392, such as titanium nitride, and a mask layer 394, such as silicon nitride.

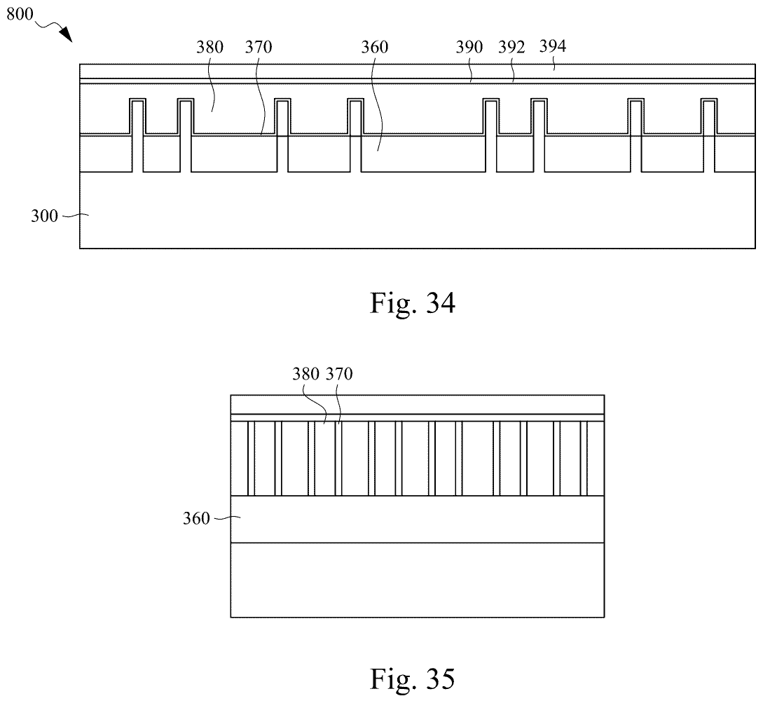

FIG. 35 illustrates the device 800, at the stage of fabrication of FIG. 34, along an X-cut passing through a metal gate, such as along line X-X in FIG. 31.

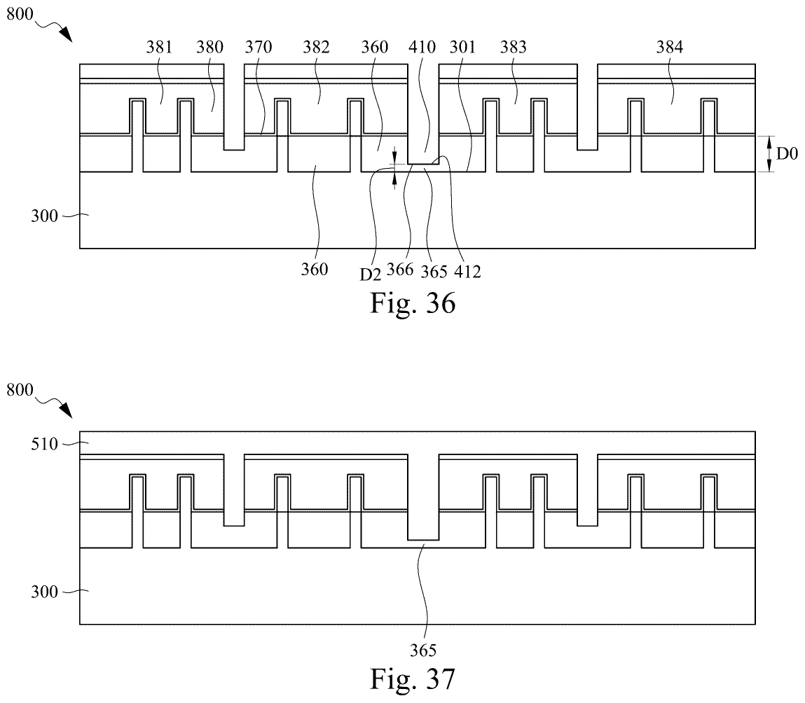

Method 900 continues at S912 as shown in FIG. 36 with performing a cut-gate or cut-metal-gate process as described above, to separate the metal gate electrode 380 into discrete metal gate segments, such as segments 381, 382, 383, and 384. These metal gate segments may be used as a metal gate of one or more FinFET.

As shown in FIG. 36, the etch process includes etching through the metal gate electrode 380, through the gate dielectric 370 and through the STI feature 360. The etch process forms a trench 410. The trench 410 has a bottom surface 412. The etch process does not extend through the STI feature 360. For example, the etch process may be timed such that a remaining portion 365 of the STI feature 360 remains under the bottom surface 412 of the trench 410 that is formed.

In FIG. 36, the trench bottom surface 412 is formed by an upper surface 366 of the remaining portion 365 of the STI feature 360. Further the trench bottom surface 412 is distanced from the upper surface 301 of the semiconductor substrate 300 by a distance D2.

As shown, the STI feature 360 has a maximum vertical thickness or distance D0, such as from the interface with the substrate to the interface with the gate dielectric layer 370. In certain embodiments, distance D2 is at least 5% of distance D0. For example, distance D2 may be at least 10%, at least 15%, at least 20%, at least 25%, at least 30%, at least 35%, at least 40%, or at least 45% of distance D0. In certain embodiments, distance D2 is at most 60% of distance D0, for example, distance D2 may be at most 55%, at most 50%, at most 45%, at most 40%, at most 35%, at most 30%, at most 25%, at most 20%, at most 15%, at most 10%, or at most 5% of distance D0.

As shown in FIG. 37, method 900 continues at S914 with depositing an insulation material 510. As shown, the insulation material 510 fills the trench 410. In accordance with some embodiments of the present disclosure, insulation material is SiO, SiN, SiC, SiCN, SiOC, SiON, SiOCN, or the like. The deposition method may include PECVD, ALD, CVD, or the like. Insulation material 510 is deposited to a level higher than the top surface of mask 390.

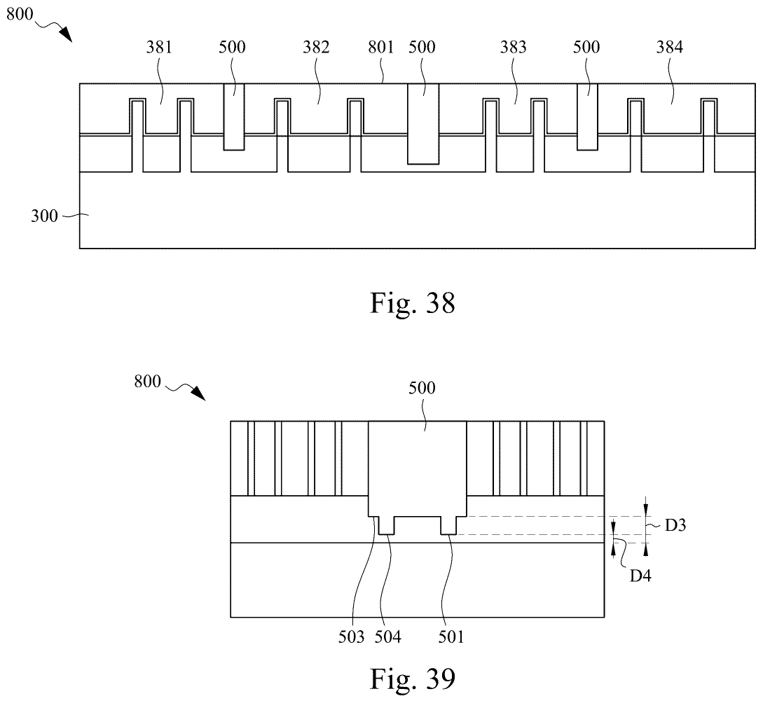

Method 900 may continue at S916 with planarizing the device 800 to remove the overburden portion of the insulation material 510 and the mask 390, and to define the cut metal gate insulation features 500 between the gate segments 381, 382, 383, and 384 as shown in FIG. 38.

FIG. 39 illustrates the device 800, at the stage of fabrication of FIG. 38, along an X-cut passing through a metal gate, such as along line X-X in FIG. 31. As shown, two parallel gate structures are cut and replaced with the cut metal gate insulation feature 500.

Cross-referencing FIGS. 38 and 39, after planarizing the device 800, the device 800 has a top surface 801 defined by the cut metal gate insulation features 500 and gate segments 381, 382, 383, and 384.

As shown, each cut metal gate insulation feature 500 has a bottom surface 501. As shown in FIG. 39, the bottom surface 501 includes a shoulder surface 503 at a distance D3 from the upper surface 301 of the semiconductor substrate 300 and a lower projection surface 504 at a distance D4 from the upper surface 301 of the semiconductor substrate 300. Distance D3 is greater than distance D4. In certain embodiments, the shoulder surface 503 is separated from the lower projection surface 504 by a vertical distance of from 5 to 70 nanometers (nm).

Method 900 may further include performing further processing at S918. For example, metallization and dielectric layers may be depositing and patterned to form contacts and electrical connections as desired.

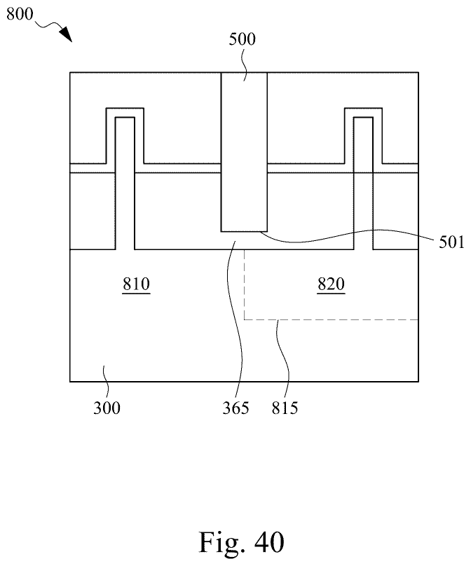

FIG. 40 illustrates a portion of the device 800 of FIG. 38. As shown, the cut metal gate insulation feature 500 lies directly over a vertical interface 815 between a well 810 of a first type of conductivity and a well 820 of a second type of conductivity. For example well 810 may be a P-well and well 820 may be an N-well.

In an embodiment herein, a method includes forming active regions over a semiconductor substrate; forming a shallow trench isolation (STI) feature over the semiconductor substrate and between the active regions, wherein the STI feature contacts an upper surface of the semiconductor substrate; forming a gate structure over the active regions and over the STI feature; cutting the gate structure by etching through the gate structure and into the STI feature to form a trench, wherein the trench is distanced from the upper surface of the semiconductor substrate; and forming an insulation feature in the trench.

In certain embodiments, the method further includes forming an etch stop layer over the upper surface of the semiconductor substrate, wherein the STI feature is formed over the etch stop layer.

In certain embodiments of the method, etching through the gate structure and into the STI feature to form the trench comprises landing on the etch stop layer.

In certain embodiments of the method, the etch stop layer has a vertical thickness and the trench is distanced from the upper surface of the semiconductor substrate by the vertical thickness.

In certain embodiments of the method, the insulation feature has an insulation bottom surface, and the insulation bottom surface contacts the etch stop layer.

In certain embodiments of the method, the insulation feature has an insulation bottom surface, and the insulation bottom surface is substantially planar.

In certain embodiments of the method, the etch stop layer does not contact the active regions.

In certain embodiments of the method, the etch stop layer lies directly over an interface between an N-well and a P-well formed in the semiconductor substrate.

In certain embodiments of the method, a remaining portion of the STI feature is located between the insulation feature and the upper surface of the semiconductor substrate.

In certain embodiments of the method, the insulation feature has an insulation bottom surface including a shoulder surface at a first distance from the upper surface of the semiconductor substrate and a lower projection surface at a second distance from the upper surface of the semiconductor substrate, wherein the second distance is less than the first distance.

In certain embodiments of the method, the shoulder surface is separated from the lower projection surface by from 5 to 70 nanometers (nm).

In another embodiment, a method includes forming an isolation feature on a semiconductor substrate; forming a metal gate over the isolation feature; forming a trench to separate the metal gate into two discrete metal gate segments, wherein the trench extends into the isolation feature and is distanced from the semiconductor substrate; and forming an insulation feature between the metal gate segments.

In certain embodiments, the method further includes forming an etch stop layer on the semiconductor substrate, the etch stop layer separates a region of the isolation feature from the semiconductor substrate, and performing the etch process comprises landing on the etch stop layer.

In certain embodiments of the method, the insulation feature has an insulation bottom surface, and wherein the insulation bottom surface contacts the etch stop layer.

In certain embodiments of the method, a remaining portion of the isolation feature is located between the insulation feature and the semiconductor substrate.

In certain embodiments of the method, the insulation feature has an insulation bottom surface including a shoulder surface at a first distance from the semiconductor substrate and a lower projection surface at a second distance from the semiconductor substrate, and wherein the shoulder surface is separated from the lower projection surface by from 5 to 70 nanometers (nm).

In another embodiment, a semiconductor device includes a semiconductor substrate; a shallow trench isolation (STI) feature over the semiconductor substrate; a first metal gate segment over the STI feature; a second metal gate segment over the STI feature; and an insulation feature located between the first metal gate segment and the second metal gate segment, wherein the insulation feature extends below the first metal gate segment and the second metal gate segment and into the STI feature, and wherein a remaining portion of the STI feature is located between the insulation feature and the semiconductor substrate to distance the insulation feature from the semiconductor substrate.

In certain embodiments of the semiconductor device, the STI feature has a maximum vertical thickness, the remaining portion has a minimum vertical distance, and the minimum vertical thickness is from 5% to 50% of the maximum vertical thickness.

In certain embodiments of the semiconductor device, the insulation feature has a bottom surface including a lower projection surface at the minimum vertical distance from the semiconductor substrate and including a shoulder surface, and the shoulder surface of is located from 5 to 70 nanometers (nm) from the lower projection surface.

In certain embodiments of the semiconductor device, the first metal gate segment, the second metal gate segment, and the insulation feature form a planar top surface.

In certain embodiments of the semiconductor device, a first well of a first conductivity type formed in the semiconductor substrate; a second well of a second conductivity type formed in the semiconductor substrate; and the insulation feature is located directly over an interface between the first well and the second well.

In another embodiment, a semiconductor device includes a semiconductor substrate; an etch stop layer located over the semiconductor substrate; a shallow trench isolation (STI) feature over the etch stop layer and the semiconductor substrate; a first metal gate segment over the STI feature; a second metal gate segment over the STI feature; and an insulation feature located between the first metal gate segment and the second metal gate segment, wherein the insulation feature extends below the first metal gate segment and the second metal gate segment and through the STI feature into contact with the etch stop layer.

In certain embodiments of the semiconductor device, the STI feature has a maximum vertical thickness, the etch stop layer has a minimum vertical thickness, and the minimum vertical thickness is from 5% to 50% of the maximum vertical thickness.

In certain embodiments of the semiconductor device, the first metal gate segment, the second metal gate segment, and the insulation feature form a planar top surface.

In certain embodiments, the semiconductor device further includes a first well of a first conductivity type formed in the semiconductor substrate, and a second well of a second conductivity type formed in the semiconductor substrate, and the etch stop layer and the insulation feature are located directly over an interface between the first well and the second well.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming active regions over a semiconductor substrate;
forming a shallow trench isolation (STI) feature over the semiconductor substrate and between the active regions, wherein the STI feature contacts an upper surface of the semiconductor substrate;
forming a gate structure over the active regions and over the STI feature;
cutting the gate structure by etching through the gate structure and into the STI feature to form a trench, wherein the trench is distanced from the upper surface of the semiconductor substrate; and
forming an insulation feature in the trench.

2. The method of claim 1, further comprising forming an etch stop layer over the upper surface of the semiconductor substrate, wherein the STI feature is formed over the etch stop layer.

3. The method of claim 2, wherein etching through the gate structure and into the STI feature to form the trench comprises landing on the etch stop layer.

4. The method of claim 3, wherein the etch stop layer has a vertical thickness and wherein the trench is distanced from the upper surface of the semiconductor substrate by the vertical thickness.

5. The method of claim 3, wherein the insulation feature has an insulation bottom surface, and wherein the insulation bottom surface contacts the etch stop layer.

6. The method of claim 3, wherein the insulation feature has an insulation bottom surface, and wherein the insulation bottom surface is substantially planar.

7. The method of claim 2, wherein the etch stop layer does not contact the active regions.

8. The method of claim 2, wherein the etch stop layer lies directly over an interface between an N-well and a P-well formed in the semiconductor substrate.

9. The method of claim 1, wherein a remaining portion of the STI feature is located between the insulation feature and the upper surface of the semiconductor substrate.

10. The method of claim 9, wherein the insulation feature has an insulation bottom surface including a shoulder surface at a first distance from the upper surface of the semiconductor substrate and a lower projection surface at a second distance from the upper surface of the semiconductor substrate, wherein the second distance is less than the first distance.

11. The method of claim 10, wherein the shoulder surface is separated from the lower projection surface by from 5 to 70 nanometers (nm).

12. A semiconductor device comprising:
a semiconductor substrate;
a shallow trench isolation (STI) feature over the semiconductor substrate;
a first metal gate segment over the STI feature;
a second metal gate segment over the STI feature; and
an insulation feature located between the first metal gate segment and the second metal gate segment, wherein the insulation feature extends below the first metal gate segment and the second metal gate segment and into the STI feature, and wherein a remaining portion of the STI feature is located between the insulation feature and the semiconductor substrate to distance the insulation feature from the semiconductor substrate.

13. The semiconductor device of claim 12, wherein the STI feature has a maximum vertical thickness, wherein the remaining portion has a minimum vertical thickness, and wherein the minimum vertical thickness is from 5% to 50% of the maximum vertical thickness.

14. The semiconductor device of claim 13, wherein the insulation feature has a bottom surface including a lower projection surface at the minimum vertical distance from the semiconductor substrate and including a shoulder surface, wherein the shoulder surface of is located from 5 to 70 nanometers (nm) from the lower projection surface.

15. The semiconductor device of claim 12, wherein the first metal gate segment, the second metal gate segment, and the insulation feature form a planar top surface.

16. The semiconductor device of claim 12, further comprising:
a first well of a first conductivity type formed in the semiconductor substrate; and
a second well of a second conductivity type formed in the semiconductor substrate, wherein the insulation feature is located directly over an interface between the first well and the second well.

17. A semiconductor device comprising:
a semiconductor substrate;
an etch stop layer located over the semiconductor substrate;
a shallow trench isolation (STI) feature over the etch stop layer and the semiconductor substrate;
a first metal gate segment over the STI feature;
a second metal gate segment over the STI feature; and
an insulation feature located between the first metal gate segment and the second metal gate segment, wherein the insulation feature extends below the first metal gate segment and the second metal gate segment and through the STI feature into contact with the etch stop layer.

18. The semiconductor device of claim 17, wherein the STI feature has a maximum vertical thickness, wherein the etch stop layer has a minimum vertical thickness, and wherein the minimum vertical thickness is from 5% to 50% of the maximum vertical thickness.

19. The semiconductor device of claim 17, wherein the first metal gate segment, the second metal gate segment, and the insulation feature form a planar top surface.

20. The semiconductor device of claim 17, further comprising:
a first well of a first conductivity type formed in the semiconductor substrate; and
a second well of a second conductivity type formed in the semiconductor substrate, wherein the etch stop layer and the insulation feature are located directly over an interface between the first well and the second well.
